(19) United States
(12) Patent Application Publication
(10) Pub. No.: US 2025/0331391 A1
(43) Pub. Date: Oct. 23, 2025

(54) DISPLAY PANEL AND PREPARATION METHOD THEREOF AND DISPLAY DEVICE

(71) Applicant: Xiamen Tianma Display Technology Co., Ltd., Xiamen (CN)

(72) Inventors: Sungwook CHANG, Xiamen (CN); Sangwon LEE, Xiamen (CN); Bing WANG, Xiamen (CN)

(73) Assignee: Xiamen Tianma Display Technology Co., Ltd., Xiamen (CN)

(21) Appl. No.: 19/259,454

(22) Filed: Jul. 3, 2025

(30) Foreign Application Priority Data
Dec. 27, 2024 (CN) 202411958155.6

(51) Int. Cl. H10K 59/80; H10K 59/12; H10K 59/122

(52) U.S. Cl. CPC H10K 59/80516; H10K 59/1201; H10K 59/122; H10K 59/80518

(57) ABSTRACT

Provided are a display panel and a preparation method thereof and a display device. The display panel includes a driving substrate and multiple light-emitting elements located on one side of the driving substrate, where different light-emitting elements among the multiple light-emitting elements have different light emission colors. The multiple light-emitting elements include first electrodes, the first electrodes include reflective electrodes, and at least part of the first electrodes each further include at least one layer of auxiliary electrodes, where the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors among the multiple light-emitting elements have different thicknesses.

### CROSS-REFERENCE TO RELATED APPLICATION(S)

This application claims priority to Chinese Patent Application No. 202411958155.6, filed on Dec. 27, 2024, the disclosure of which is incorporated herein by reference in its entirety.

### TECHNICAL FIELD

Embodiments of the present disclosure relate to the field of display technology and, in particular, to a display panel and a preparation method thereof and a display device.

### BACKGROUND

With the continuous development of display technology, display panels have been widely applied in production and life. To better meet people's requirements, the display panels can be adjusted. For example, some films in the display panels are adjusted, thereby improving overall effects of the display panels.

### SUMMARY

Embodiments of the present disclosure provide a display panel and a preparation method thereof and a display device. Thicknesses of auxiliary electrodes in light-emitting elements with different colors are adjusted to be different, thereby adjusting light emission effects of the light-emitting elements with the different colors and improving a display effect of the entire display panel.

In a first aspect, embodiments of the present disclosure provide a display panel. The display panel includes a driving substrate and multiple light-emitting elements located on one side of the driving substrate, where different light-emitting elements among the multiple light-emitting elements have different light emission colors.

The multiple light-emitting elements include first electrodes, the first electrodes include reflective electrodes, and at least part of the first electrodes each further include at least one layer of auxiliary electrodes, where the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors among the multiple light-emitting elements have different thicknesses.

In a second aspect, embodiments of the present disclosure provide a preparation method of a display panel. The display panel includes multiple light-emitting elements located on one side of the driving substrate, where different light-emitting elements among the multiple light-emitting elements have different light emission colors.

The preparation method includes the steps described below.

A driving substrate is prepared.

First electrodes are prepared on one side of the driving substrate, where the first electrodes include reflective electrodes, and at least part of the first electrodes each further include at least one layer of auxiliary electrodes, where the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors among the multiple light-emitting elements have different thicknesses.

In a third aspect, embodiments of the present disclosure provide a display device. The display panel includes the display panel described in the first aspect.

The embodiments of the present disclosure provide the display panel. The display panel includes the multiple light-emitting elements located on the one side of the driving substrate, and the driving substrate drives the light-emitting elements to perform light-emitting display, thereby implementing a display function of the display panel. Further, the light-emitting element includes a first electrode, and first electrodes of light-emitting elements of different colors may have different thicknesses. The thicknesses of the first electrodes are adjusted so that light emission effects of the light-emitting elements of the different colors are adjusted, thereby ensuring the display uniformity of the entire display panel. Specifically, in the multiple light-emitting elements, at least some first electrodes include auxiliary electrodes. Thicknesses of auxiliary electrodes of the light-emitting elements of the different colors are adjusted so that the thicknesses of the first electrodes are adjusted and the light emission effects of the light-emitting elements of the different colors are adjusted, thereby ensuring a display effect of the display panel.

It is to be understood that the content described in this section is neither intended to identify key or critical features of embodiments of the present disclosure nor intended to limit the scope of the present disclosure. Other features of the present disclosure become easily understood through the description provided hereinafter.

### BRIEF DESCRIPTION OF DRAWINGS

To illustrate technical solutions in example embodiments of the present disclosure more clearly, the drawings used in the description of the embodiments are briefly described below. Apparently, the described drawings are only part, not all, of drawings of the embodiments of the present disclosure to be described, and those of ordinary skill in the art may obtain other drawings based on the drawings described below on the premise that no creative work is done.

FIG. 1 is a structure diagram of a display panel in the related art.

FIG. 2 is a structure diagram of a display panel according to an embodiment of the present disclosure.

FIG. 3 is a first sectional view of FIG. 2 taken along a line A-A′.

FIG. 4 is a second sectional view of FIG. 2 taken along a line A-A′.

FIG. 5 is a third sectional view of FIG. 2 taken along a line A-A′.

FIG. 6 is a fourth sectional view of FIG. 2 taken along a line A-A′.

FIG. 7 is a fifth sectional view of FIG. 2 taken along a line A-A′.

FIG. 8 is an enlarged view of a light-emitting element in FIG. 3.

FIG. 9 is an enlarged view of another light-emitting element in FIG. 3.

FIG. 10 is a structure diagram of a first light-emitting element according to an embodiment of the present disclosure.

FIG. 11 is a structure diagram of a second light-emitting element according to an embodiment of the present disclosure.

FIG. 12 is a flowchart of a first preparation method of a display panel according to an embodiment of the present disclosure.

FIG. 13 is a flowchart of a second preparation method of a display panel according to an embodiment of the present disclosure.

FIG. 14 is a flowchart of a third preparation method of a display panel according to an embodiment of the present disclosure.

FIG. 15 is a schematic diagram of a first preparation process of a display panel according to an embodiment of the present disclosure.

FIG. 16 is a flowchart of a fourth preparation method of a display panel according to an embodiment of the present disclosure.

FIG. 17 is a schematic diagram of a second preparation process of a display panel according to an embodiment of the present disclosure.

FIG. 18 is a flowchart of a fifth preparation method of a display panel according to an embodiment of the present disclosure.

FIG. 19 is a schematic diagram of a third preparation process of a display panel according to an embodiment of the present disclosure.

FIG. 20 is a flowchart of a sixth preparation method of a display panel according to an embodiment of the present disclosure.

FIG. 21 is a schematic diagram of a seventh preparation process of a display panel according to an embodiment of the present disclosure.

FIG. 22 is a flowchart of a seventh preparation method of a display panel according to an embodiment of the present disclosure.

FIG. 23 is a schematic diagram of an eighth preparation process of a display panel according to an embodiment of the present disclosure.

FIG. 24 is a structure diagram of a display device according to an embodiment of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

It is to be noted that terms such as “first” and “second” in the description, claims, and above drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. Additionally, terms “including”, “having”, and any variations thereof are intended to encompass a non-exclusive inclusion. For example, a system, product, or device that includes a series of units not only includes the expressly listed steps or units but may also include other units that are not expressly listed or are inherent to the product or device.

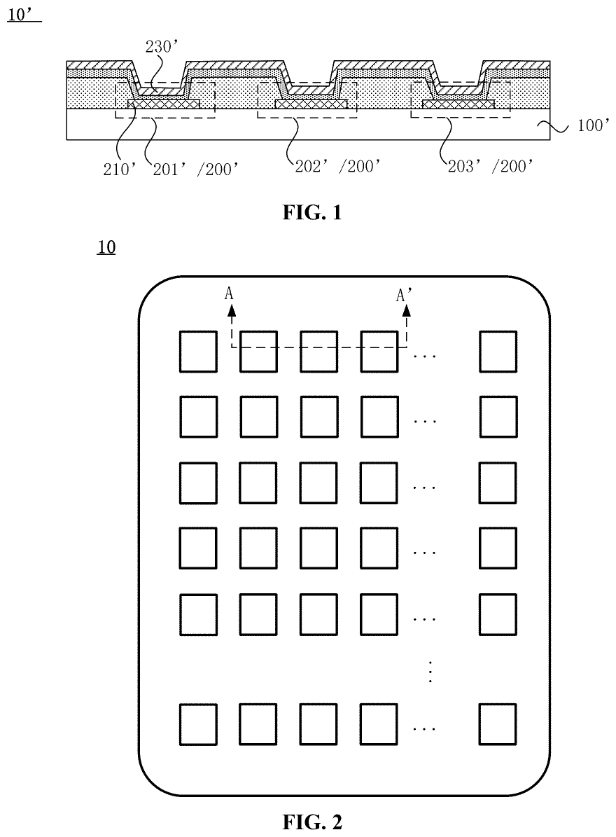

FIG. 1 is a structure diagram of a display panel in the related art. As shown in FIG. 1, the display panel 10′ includes a driving substrate 100′ and multiple light-emitting elements 200′ located on one side of the driving substrate 100′, and the light-emitting elements 200′ include light-emitting elements 200′ in different colors, for example, a first color light-emitting element 201′, a second color light-emitting element 202′ and a third color light-emitting element 203′. The light-emitting elements 200′ in the different colors have different emission wavelengths. For light generated in the light-emitting elements 200′, one portion of the light is emitted at a second electrode 230′, and the other portion of the light is reflected back to a first electrode 210′ at the second electrode 230′. In this manner, the light is reflected multiple times, constructive interference occurs in light with a particular wavelength and improves the intensity of the light, and a remaining wavelength disappears due to destructive interference. Since emission light in the first color light-emitting element 201′, the second color light-emitting element 202′ and the third color light-emitting element 203′ has different wavelengths, the reflection of the light with the different wavelengths in the first electrode 210′ and a third electrode 230′ causes a difference in an entire light emission effect, thereby affecting the display uniformity of the entire display panel 10′.

Based on the above technical problems, an embodiment of the present disclosure provides a display panel. The display panel includes multiple light-emitting elements located on one side of a driving substrate, and the driving substrate drives the light-emitting elements to perform light-emitting display, thereby implementing a display function of the display panel. Further, the light-emitting element includes a first electrode, and first electrodes of light-emitting elements of different colors may have different thicknesses. The thicknesses of the first electrodes are adjusted so that light emission effects of the light-emitting elements of the different colors are adjusted, thereby ensuring the display uniformity of the entire display panel. Specifically, in the multiple light-emitting elements, at least some first electrodes further include auxiliary electrodes. Thicknesses of auxiliary electrodes of the light-emitting elements of the different colors are adjusted so that the thicknesses of the first electrodes are adjusted and the light emission effects of the light-emitting elements of the different colors are adjusted, thereby ensuring a display effect of the display panel.

The preceding is the core idea of the present disclosure. The technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without any creative efforts are within the scope of the present disclosure.

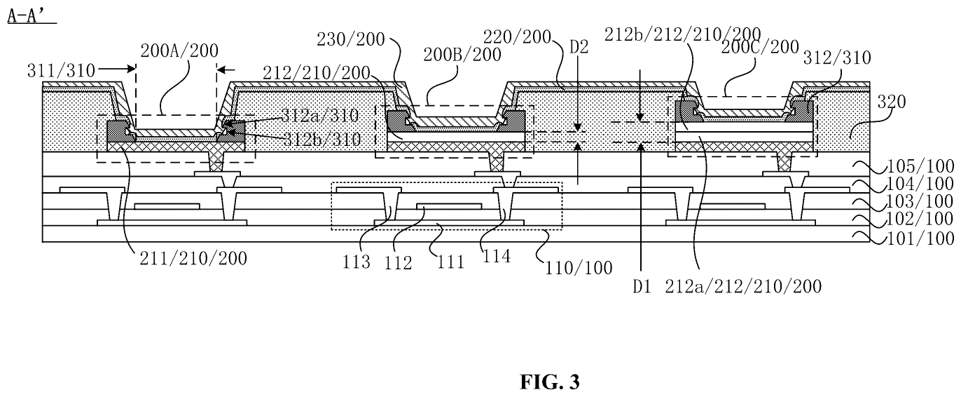

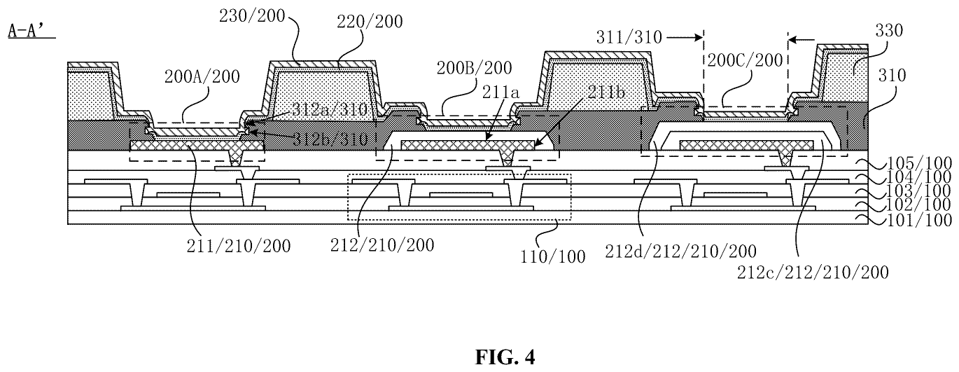

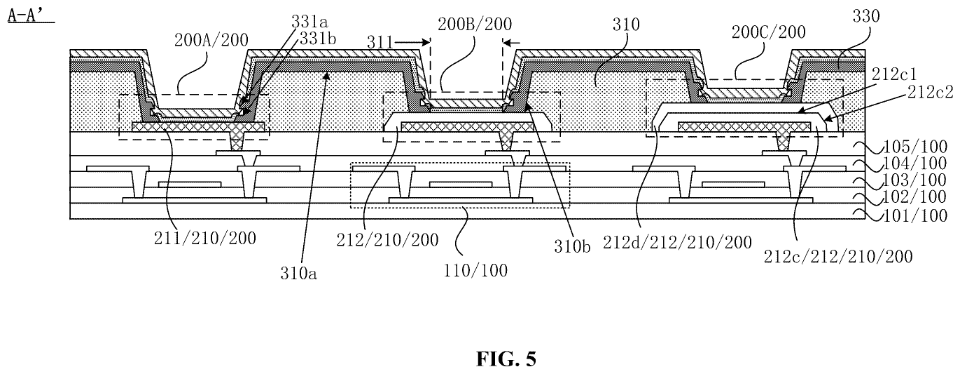

FIG. 2 is a structure diagram of a display panel according to an embodiment of the present disclosure. FIG. 3 is a first sectional view of FIG. 2 taken along a line A-A′. FIG. 4 is a second sectional view of FIG. 2 taken along a line A-A′. FIG. 5 is a third sectional view of FIG. 2 taken along a line A-A′. Referring to FIGS. 2 to 5, an embodiment of the present disclosure provides a display panel 10. The display panel 10 includes a driving substrate 100 and multiple light-emitting elements 200 located on one side of the driving substrate 100, where different light-emitting elements 200 have different light emission colors. The light-emitting elements 200 include first electrodes 210, the first electrodes 210 include reflective electrodes 211, and at least some first electrodes 211 each further include at least one layer of auxiliary electrodes 212, where the reflective electrodes 211 are electrically connected to a driver circuit 110 in the driving substrate 100, the auxiliary electrodes 212 are located on a side of a reflective electrode 211 facing away from the driving substrate 100, and auxiliary electrodes 212 in the light-emitting elements 200 with the different light emission colors have different thicknesses.

Referring to FIGS. 2 to 5, the display panel 10 includes the driving substrate 100 and the multiple light-emitting elements 200 located on the one side of the driving substrate 100, the driving substrate 100 includes the driver circuit 110, and the driver circuit 110 is electrically connected to the light-emitting elements 200. The driver circuit 110 can provide a drive current for the light-emitting elements 200 to drive the light-emitting elements 200 to perform light-emitting display, thereby implementing a display function of the display panel 10. Further, the driver circuit 110 in the driving substrate 100 may include a transistor, and the transistor may include an active layer 111, a gate 112, a source 113 and a drain 114. Moreover, the driver circuit 110 is disposed in diverse manners and may be, for example, “7T1C” or “8T2C”, where “T” denotes a transistor, and “C” denotes a capacitor. A specific manner of disposing the driver circuit 110 in the driving substrate 100 may be adaptively adjusted according to different display panels 10 and is not specifically limited in the embodiment of the present disclosure.

Further, referring to FIGS. 3 to 5, the driving substrate 100 may include a substrate 101, a gate insulating layer 102, a first interlayer insulating layer 103, a second interlayer insulating layer 104 and a planarization layer 105, and the gate insulating layer 102, the first interlayer insulating layer 103, the second interlayer insulating layer 104 and the planarization layer 105 may be disposed between two adjacent metal layers to play a role in signal isolation and planarization.

Further, the light-emitting elements 200 may include light-emitting elements of different colors, for example, a red light-emitting element, a blue light-emitting element and a green light-emitting element. The light-emitting elements 200 of the different colors are disposed, thereby implementing a color display effect of the display panel 10. Multiple light-emitting elements 200 of different colors are also arranged in diverse manners in the display panel 10. For the diverse manners, no more examples are given in the embodiment of the present disclosure.

Specifically, referring to FIGS. 3 to 5, the light-emitting element 200 includes the first electrode 210 and is electrically connected to the driver circuit 110 via the first electrode 210. In other words, the drive current provided by the driver circuit 110 is transmitted to the light-emitting element 200 via the first electrode 210. Further, the light-emitting element 200 further includes a light-emitting layer 220 and a second electrode 230, and the light-emitting layer 220 is located between the first electrode 210 and the second electrode 230. A light emission principle of the light-emitting element 200 may be understood as follows: a certain electric signal is separately applied to the first electrode 210 and the second electrode 230, and holes from the first electrode 210 and electrons from the second electrode 230 converge in the light-emitting layer 220 and are further excited in the light-emitting layer 220 to emit light, thereby implementing the light emission of the light-emitting element 200.

Further, referring to FIGS. 3 to 5, the first electrode 210 includes the reflective electrode 211, and the second electrode 230 may be a semi-transmissive and semi-reflective electrode. Excited in the light-emitting layer, emitted light can be reflected for multiple times in a microcavity formed by the reflective electrode 211 and the second electrode 230, and constructive interference occurs in light with a particular wavelength, thereby enhancing light intensity. Constructive interference occurs when a distance between the first electrode 210 and the second electrode 230 is integer times a wavelength of transmitted light. The relational expression is as follows:

$$d = n * ( λ / 2 )$$

where d denotes a distance between the reflective electrode 211 and the second electrode 230.

As can be seen from the above relational expression, to ensure constructive interference, it needs to be ensured that the distance between the reflective electrode 211 and the second electrode 230 satisfies integer times the wavelength, that is, a distance between a reflective electrode 211 and a second electrode 230 in a light-emitting element with a long emission wavelength needs to be long. Therefore, in the embodiment of the present disclosure, a thickness of the auxiliary electrode is adjusted so that the distance between the reflective electrode 211 and the second electrode 230 is adjusted. Specifically, auxiliary electrodes in light-emitting elements with different light emission colors have different thicknesses. Specifically, in a light-emitting element with a relatively long light emission wavelength, an auxiliary electrode has a relatively large thickness, and in a light-emitting element with a relatively short light emission wavelength, an auxiliary electrode has a relatively small thickness. The thickness of the auxiliary electrode is adjusted so that a cavity length of microcavity effect is adjusted, thereby ensuring that constructive interference can occur in light emission of different colors in the microcavity and improving light emission intensity.

Further, referring to FIGS. 3 to 5, at least some first electrodes 211 further include auxiliary electrodes 212, and thicknesses of auxiliary electrodes 212 in light-emitting elements 200 of different colors may be set differently. Referring to FIGS. 3 to 5, no auxiliary electrode 212 may be disposed in a first electrode 210 of a light-emitting element 200A, and an auxiliary electrode 212 may be disposed in both a first electrode 210 of a light-emitting element 200B and a first electrode 210 of a light-emitting element 200C. Moreover, a thickness of the auxiliary electrode 212 in the light-emitting element 200B may be less than a thickness of the auxiliary electrode 212 in the light-emitting element 200C. The auxiliary electrode 212 is disposed, and thicknesses of auxiliary electrodes 212 in light-emitting elements 200 of different colors are adjusted to be different, thereby implementing different gaps between reflective electrodes 211 and second electrodes 230 in the light-emitting elements 200 of the different colors. For example, a wavelength of the red light-emitting element is longer than a wavelength of the green light-emitting element, and a thickness of an auxiliary electrode 212 in the red light-emitting element may be adjusted to be greater than a thickness of an auxiliary electrode 212 in the green light-emitting element; the wavelength of the green light-emitting element is longer than a wavelength of the blue light-emitting element, and the thickness of the auxiliary electrode 212 in the green light-emitting element may be adjusted to be greater than a thickness of an auxiliary electrode 212 in the blue light-emitting element.

In conclusion, the display panel provided in the embodiment of the present disclosure includes multiple light-emitting elements of different colors, and auxiliary electrodes in the light-emitting elements of the different colors have different thicknesses. Microcavity lengths of microcavity effect in different light-emitting elements are adjusted according to the different thicknesses of the auxiliary electrodes, thereby enhancing the light emission intensity of the light-emitting elements of the different colors and ensuring a display effect of the display panel.

With continued reference to FIGS. 3 to 5, the light-emitting elements 200 with the different light emission colors include a first light-emitting element and a second light-emitting element, where the first light-emitting element includes a red light-emitting element or a green light-emitting element, and the second light-emitting element includes a blue light-emitting element; or the first light-emitting element includes a red light-emitting element, and the second light-emitting element includes a green light-emitting element or a blue light-emitting element. The number of layers of auxiliary electrodes 212 in the first light-emitting element is greater than the number of layers of auxiliary electrodes 212 in the second light-emitting element.

Further, in light-emitting elements 200 of different colors, different numbers of layers of auxiliary electrodes 212 may be set to implement a manner of setting different thicknesses of the auxiliary electrodes 212 in the light-emitting elements 200 of the different colors. Specifically, the light-emitting elements 200 include the first light-emitting element and the second light-emitting element, and a light emission color of the first light-emitting element is different from a light emission color of the second light-emitting element. Thicknesses of the auxiliary electrodes 212 can be adjusted in conjunction with the light emission colors according to the above microcavity effect.

A wavelength of red light is longer than a wavelength of green light, and the wavelength of the green light is longer than a wavelength of blue light. In the case where the first light-emitting element is a red light-emitting element or a green light-emitting element and the second light-emitting element is a blue light-emitting element, the number of layers of auxiliary electrodes 212 in the first light-emitting element may be adjusted to be greater than the number of layers of auxiliary electrodes 212 in the second light-emitting element. Alternatively, in the case where the first light-emitting element is a red light-emitting element and the second light-emitting element is a green light-emitting element or a blue light-emitting element, the number of layers of auxiliary electrodes 212 in the first light-emitting element may be adjusted to be greater than the number of layers of auxiliary electrodes 212 in the second light-emitting element.

For example, referring to FIGS. 3 to 5, the light-emitting elements 200 include the light-emitting element 200A, the light-emitting element 200B and the light-emitting element 200C, and the light-emitting element 200A, the light-emitting element 200B and the light-emitting element 200C emit light of different colors, respectively. The light-emitting element 200A may be understood as a blue light-emitting element, the light-emitting element 200B may be understood as a green light-emitting element, and the light-emitting element 200C may be understood as a red light-emitting element. The number of layers of auxiliary electrodes 212 in the light-emitting element 200C is two, the number of layers of auxiliary electrodes 212 in the light-emitting element 200B is one, and no auxiliary electrode 212 is disposed in the light-emitting element 200A, thereby differently setting the numbers of layers of auxiliary electrodes 212 in light-emitting elements 200 of different colors. With a comparison between the light-emitting element 200A and the light-emitting element 200B, the light-emitting element 200A may be considered as the second light-emitting element, and the light-emitting element 200B may be considered as the first light-emitting element. With a comparison between the light-emitting element 200A and the light-emitting element 200C, the light-emitting element 200A may be considered as the second light-emitting element, and the light-emitting element 200C may be considered as the first light-emitting element. With a comparison between the light-emitting element 200B and the light-emitting element 200C, the light-emitting element 200B may be considered as the second light-emitting element, and the light-emitting element 200C may be considered as the first light-emitting element.

In general, in the display panel 10, the numbers of layers of auxiliary electrodes 212 in first electrodes 210 may be adaptively adjusted according to specific light emission colors of different light-emitting elements 200, thereby ensuring that cavity lengths of microcavity effect are matched with emission wavelengths of the different light-emitting elements in the different light-emitting elements, ensuring that an effect of enhancing light emission can be obtained and ensuring the display effect of the entire display panel 10.

It is to be noted that a manner of disposing auxiliary electrodes in light-emitting elements with different light emission colors is illustrated only in a possible manner in FIGS. 3 to 5. Specific thicknesses/specific numbers of layers of the auxiliary electrodes in the light-emitting elements with the different light emission colors are not limited in the embodiment of the present disclosure. For example, an auxiliary electrode may also be disposed in the light-emitting element 200A, and the number of layers of auxiliary electrodes in the light-emitting element 200A may be one, two or more. It only needs to be ensured that a thickness of an auxiliary electrode/the number of layers of auxiliary electrodes in a light-emitting element with a relatively long emission wavelength is greater than that of a light-emitting element with a relatively short emission wavelength. Alternatively, it only needs to be ensured that the thickness of the auxiliary electrode/the number of layers of auxiliary electrodes in the red light-emitting element is greater than that of the green light-emitting element and the thickness of the auxiliary electrode/the number of layers of auxiliary electrodes in the green light-emitting element is greater than that of the blue light-emitting element. Moreover, thicknesses of auxiliary electrodes/the numbers of layers of auxiliary electrodes in different light-emitting elements may be set according to cavity lengths required for microcavity effect in the different light-emitting elements.

With continued reference to FIG. 3, light-emitting elements 200 with auxiliary electrodes 212 include a seventh light-emitting element and an eighth light-emitting element. A thickness of an auxiliary electrode 212 in the seventh light-emitting element is D1, and a thickness of an auxiliary electrode 212 in the eighth light-emitting element is D2, where (n+1)/n≤ D1/D2≤(n+1)/1, and n is a positive number.

The light-emitting element 200 includes the seventh light-emitting element and the eighth light-emitting element, and the auxiliary electrode 212 is disposed in both the seventh light-emitting element and the eighth light-emitting element. In conjunction with FIG. 3, for the seventh light-emitting element and the eighth light-emitting element, reference may be made to the light-emitting element 200B and the light-emitting element 200C in FIG. 3. An emission wavelength of the seventh light-emitting element is different from an emission wavelength of the eighth light-emitting element, that is, a light emission color of the seventh light-emitting element is different from a light emission color of the eighth light-emitting element. Further, a difference may exist between the thickness of the auxiliary electrode 212 in the seventh light-emitting element and the thickness of the auxiliary electrode 212 in the eighth light-emitting element, and cavity lengths required for light emission wavelengths are adjusted according to the difference between the thicknesses of the auxiliary electrodes 212, thereby meeting microcavity effect and improving light emission effects of the light-emitting elements 200.

Specifically, the thickness of the auxiliary electrode 212 in the seventh light-emitting element is D1, the thickness of the auxiliary electrode 212 in the eighth light-emitting element is D2, and (n+1)/n≤D1/D2≤(n+1)/1 is satisfied. Since n is a positive number, it may be understood that D1>D2, that is, the thickness of the auxiliary electrode 212 in the seventh light-emitting element is greater than the thickness of the auxiliary electrode 212 in the eighth light-emitting element, thereby reflecting that auxiliary electrodes in light-emitting elements 200 with different light emission colors have different thicknesses. For example, referring to FIG. 3, the seventh light-emitting element may be understood as the light-emitting element 200C in FIG. 3, the eighth light-emitting element may be understood as the light-emitting element 200B in FIG. 3, and the thickness of the entire auxiliary electrode 212 shown in the light-emitting element 200C is greater than the thickness of the entire auxiliary electrode 212 shown in the light-emitting element 200B.

Further, for example, when n is 1, the relational expression between D1 and D2 satisfies: (1+1)/1≤D1/D2≤(1+1)/1, where D1/D2 is 2. For example, when n is 2, the relational expression between D1 and D2 satisfies: (2+1)/2≤D1/D2≤(2+1)/1, that is, 3/2≤D1/D2≤3. In this case, D1/D2 may be any value between 3/2 and 3, for example, 3/2, 1.8, 2, 2.15, 2.5, 2.8 or 3. For example, when n is 3, the relational expression between D1 and D2 satisfies: (3+1)/3≤D1/D2≤(3+1)/1, that is, 4/3≤D1/D2≤4. In this case, D1/D2 may be any value between 4/3 and 4, for example, 4/3, 1.5, 1.8, 2, 2.15, 2.5, 2.8, 3, 3.2, 3.4, 3.7 or 4. For example, when n is 4, the relational expression between D1 and D2 satisfies: (4+1)/4≤D1/D2≤(4+1)/1, that is, 5/4≤ D1/D2≤5. In this case, D1/D2 may be any value between 5/4 and 5, for example, 5/4, 4/3, 1.5, 1.8, 2, 2.2, 2.5, 2.8, 3, 3.2, 3.4, 3.7, 4, 4.25, 4.5, 4.68, 4.83 or 5. In other words, for the difference between the thickness of the auxiliary electrode in the seventh light-emitting element and the thickness of the auxiliary electrode in the eighth light-emitting element, auxiliary electrodes 212 with the same thickness may be disposed in different layers.

In general, for different thicknesses of auxiliary electrodes 212 corresponding to light-emitting elements 200 with different light emission colors, a difference may exist between the thicknesses of the auxiliary electrodes 212 disposed at the light-emitting elements 200 with the different light emission colors; or different numbers of layers of auxiliary electrodes 212 may be disposed at the light-emitting elements 200 with the different light emission colors; or different numbers of layers of auxiliary electrodes 212 may be disposed at the light-emitting elements 200 with the different light emission colors, and the auxiliary electrodes 212 may also have different thicknesses. A difference between thicknesses of entire auxiliary electrodes 212 in light-emitting elements 200 with different light emission colors is reflected, and the auxiliary electrodes 212 are disposed in diverse manners.

With continued reference to FIG. 3, the multiple light-emitting elements 200 include a third light-emitting element, and the third light-emitting element includes at least one layer of auxiliary electrodes 212. An area of the auxiliary electrodes 212 is S1, and an area of a reflective electrode 211 is S2, where |S1−S2|/S1≤10%.

Specifically, the light-emitting elements 200 include the third light-emitting element, and the third light-emitting element includes the at least one layer of auxiliary electrodes 212. In conjunction with FIG. 3, for the third light-emitting element, reference may be made to the light-emitting element 200B or the light-emitting element 200C in FIG. 3.

Further, referring to FIG. 3, the area of the auxiliary electrode 212 is S1, and the area of the reflective electrode 211 is S2, where S1 and S2 satisfy: |S1−S2|/S1≤10%. It may be understood that values of S1 and S2 are the same or similar. It may also be considered that an orthographic projection of the auxiliary electrode 212 on one side of the driving substrate 100 substantially coincides with an orthographic projection of the reflective electrode 211 on one side of the driving substrate 100.

Further, when a size of the auxiliary electrode 212 in the third light-emitting element is adjusted to be the same as or similar to a size of the reflective electrode 211 in the third light-emitting element, an occupied area of the light-emitting element 200 in the display panel 10 is not increased due to the addition of the auxiliary electrode 212 to the light-emitting element 200. It is conducive to disposing the display panel 10 in a manner with a high pixel density and improving the display effect of the entire display panel 10. Further, when the size of the auxiliary electrode 212 additionally disposed in the light-emitting element 200 is the same as or similar to the size of the reflective electrode 211 in the light-emitting element 200, the regularity of the entire light-emitting element 200 can also be ensured, and the auxiliary electrode 212 and the reflective electrode 211 can be prepared by using the same etching protective layer, thereby reducing the process preparation difficulty of the display panel 10 and reducing a process preparation cost of the display panel 10.

With continued reference to FIG. 3, the multiple light-emitting elements 200 include a fourth light-emitting element, the fourth light-emitting element includes at least two layers of stacked auxiliary electrodes 212, and the at least two layers of auxiliary electrodes 212 include a first auxiliary electrode 212a and a second auxiliary electrode 212b. An area of the first auxiliary electrode 212a is S3, and an area of the second auxiliary electrode 212b is S4, where |S3−S4/S3≤10%.

Specifically, the light-emitting elements 200 further include the fourth light-emitting element, and the at least two layers of auxiliary electrodes 212 are disposed in the fourth light-emitting element. In conjunction with FIG. 3, for the fourth light-emitting element, reference may be made to the light-emitting element 200C in FIG. 3. Two layers of auxiliary electrodes 212 being included in the light-emitting element 200C in FIG. 3 is used as an example for description, and the specific number of layers of disposed auxiliary electrodes 212 in the fourth light-emitting element may also be adaptively adjusted according to an actual requirement and is not specifically limited in the embodiment of the present disclosure.

Further, referring to FIG. 3, two layers of auxiliary electrodes 212 are included in the light-emitting element 200C. The two layers of auxiliary electrodes 212 are a first auxiliary electrode 212a and a second auxiliary electrode 212b, respectively. An area of the first auxiliary electrode 212a is S3, and an area of the second auxiliary electrode 212b is S4, where S3 and S4 satisfy: |S3−S4|/S3≤10%. It may be understood that values of S3 and S4 are the same or similar. It may also be considered that an orthographic projection of the first auxiliary electrode 212a on one side of the driving substrate 100 substantially coincides with an orthographic projection of the second auxiliary electrode 212b on one side of the driving substrate 100.

Further, the two layers of auxiliary electrodes 212 disposed in the fourth light-emitting element can improve a light emission effect of the light-emitting element 200. Moreover, when sizes of the two layers of auxiliary electrodes 212 in the fourth light-emitting element are adjusted to be the same or similar, an occupied area of the light-emitting element 200 in the display panel 10 is not increased due to the increase of the number of disposed auxiliary electrodes 212 to the light-emitting element 200. It is conducive to disposing the display panel 10 in a manner with a high pixel density and improving the display effect of the entire display panel 10. Further, when sizes of multiple layers of auxiliary electrodes 212 additionally disposed in the light-emitting element 200 are the same or similar, the regularity of the entire light-emitting element 200 can also be ensured, and the multiple layers of auxiliary electrodes 212 can also be prepared by using the same etching protective layer, thereby reducing the process preparation difficulty of the display panel 10 and reducing the process preparation cost of the display panel 10.

With continued reference to FIGS. 4 and 5, the multiple light-emitting elements 200 include a fifth light-emitting element, and the fifth light-emitting element 200 includes at least one layer of auxiliary electrodes 212. The auxiliary electrodes 212 cover an upper surface on a side of a reflective electrode 211 facing away from the driving substrate 100 and a side surface connected to the upper surface.

Specifically, the light-emitting elements 200 include the fifth light-emitting element, and the fifth light-emitting element includes the at least one layer of auxiliary electrodes 212. In conjunction with FIGS. 4 and 5, for the fifth light-emitting element, reference may be made to the light-emitting element 200B in FIGS. 4 and 5, and one layer of auxiliary electrodes 212 being included in the fifth light-emitting element in FIGS. 4 and 5 is used as an example for description.

Further, referring to FIGS. 4 and 5, an orthographic projection of the auxiliary electrode 212 on one side of the driving substrate 100 covers an orthographic projection of the reflective electrode 211 on one side of the driving substrate 100, and the auxiliary electrode 212 covers the upper surface on the side of the reflective electrode 211 facing away from the driving substrate 100 (referring to 211a in FIG. 4) and the side surface connected to the upper surface (referring to 211b in FIG. 4). It may be understood that the reflective electrode 211 is coated with the auxiliary electrode 212 disposed on the side of the reflective electrode 211 facing away from the driving substrate 100.

Further, a size of the auxiliary electrode 212 is adjusted to be greater than a size of the reflective electrode 211, and the auxiliary electrode 212 can cover the reflective electrode 211. In this manner, it can be ensured that the auxiliary electrode 212 is disposed on a propagation path of light reflected by the reflective electrode 211, that is, a cavity length of microcavity effect of the light reflected by the reflective electrode 211 can be adjusted according to the auxiliary electrode 212, thereby ensuring that microcavity effect is sufficient and light emission intensity is adjusted sufficiently.

With continued reference to FIGS. 4 and 5, the multiple light-emitting elements 200 include a sixth light-emitting element, the sixth light-emitting element includes at least two layers of stacked auxiliary electrodes 212, and the at least two layers of auxiliary electrodes 212 include a third auxiliary electrode 212c and a fourth auxiliary electrode 212d, where the fourth auxiliary electrode 212d is located on a side of the third auxiliary electrode 212c facing away from the driving substrate 100. The fourth auxiliary electrode 212d covers an upper surface on the side of the third auxiliary electrode 212c facing away from the driving substrate 100 and a side surface connected to the upper surface.

Specifically, the light-emitting elements 200 include the sixth light-emitting element, and the sixth light-emitting element includes the at least two layers of auxiliary electrodes 212. In conjunction with FIGS. 4 and 5, for the sixth light-emitting element, reference may be made to the light-emitting element 200C in FIGS. 4 and 5, and two layers of auxiliary electrodes 212 being included in the sixth light-emitting element in FIGS. 4 and 5 is used as an example for description. In fact, the auxiliary electrodes 212 include the third auxiliary electrode 212c and the fourth auxiliary electrode 212d, and the fourth auxiliary electrode 212d is located on the one side of the third auxiliary electrode 212c facing away from the driving substrate 100.

Further, referring to FIGS. 4 and 5, an orthographic projection of the fourth auxiliary electrode 212d on one side of the driving substrate 100 covers an orthographic projection of the third auxiliary electrode 212c on one side of the driving substrate 100, and the fourth auxiliary electrode 212d covers the upper surface on the side of the third auxiliary electrode 212c facing away from the driving substrate 100 (referring to 212cl in FIG. 5) and the side surface connected to the upper surface (referring to 212c2 in FIG. 5). It may be understood that the third auxiliary electrode 212c is coated with the fourth auxiliary electrode 212d disposed on the side of the third auxiliary electrode 212c facing away from the driving substrate 100.

Further, a size of the fourth auxiliary electrode 212d is adjusted to be greater than a size of the third auxiliary electrode 212c, and the fourth auxiliary electrode 212d can cover the third auxiliary electrode 212c. In this manner, it can be ensured that light subjected to cavity length adjustment according to the third auxiliary electrode 212c can be subjected to cavity length adjustment again according to the fourth auxiliary electrode 212d, thereby ensuring that a microcavity is adjusted sufficiently and light emission intensity is adjusted sufficiently.

With continued reference to FIGS. 3 and 4, the display panel 10 further includes a first pixel defining structure 310 at least partially located on a side of a first electrode 210 facing away from the driving substrate 100, where a pixel opening 311 is disposed in the first pixel defining structure 310, penetrates through the first pixel defining structure 310 and exposes at least a portion of the first electrode 210. The first pixel defining structure 310 covers a portion of an upper surface on the side of the first electrode 210 facing away from the driving substrate 100.

Further, the display panel 10 further includes the first pixel defining structure 310, and the first pixel defining structure 310 includes the pixel opening 311. The pixel opening 311 may be understood as a hollowed-out area of the first pixel defining structure 310 or may be understood as an opening region formed after the first pixel defining structure 310 is subjected to patterned etching. Further, referring to FIGS. 3 and 4, the first pixel defining structure 310 covers a portion of the upper surface on the side of the first electrode 210 facing away from the driving substrate 100, that is, at least a portion of the region of the first pixel defining structure 310 is located on the side of the first electrode 210 facing away from the driving substrate 100. A material of the first pixel defining structure 310 may be an organic structure or an inorganic structure and is not specifically limited in the embodiment of the present disclosure.

With continued reference to FIG. 3, the first pixel defining structure 310 includes multiple pixel defining sub-structures 312 disposed independently, where each of the multiple pixel defining sub-structures 312 corresponds to a respective one of the multiple light-emitting elements 200. Each of the multiple pixel defining sub-structures 312 covers a portion of an upper surface on a side of a first electrode 210 facing away from the driving substrate 100 in a light-emitting element 200 corresponding to the pixel defining sub-structure 312, and an orthographic projection of the pixel defining sub-structure 312 on a plane where the driving substrate 100 is located is located within an orthographic projection of a first electrode 210 in a light-emitting element 200 corresponding to the pixel defining sub-structure 312 on the plane where the driving substrate 100 is located.

Referring to FIG. 3, the first pixel defining structure 310 includes the multiple pixel defining sub-structures 312, the pixel defining sub-structure 312 is located on the upper surface on the side of the first electrode 210 facing away from the driving substrate 100, and the orthographic projection of the pixel defining sub-structure 312 on the driving substrate 100 is located within the orthographic projection region of the first electrode 210 in the light-emitting element 200 corresponding to the pixel defining sub-structure 312 on the driving substrate 100. It may be understood that referring to FIG. 3, the pixel defining sub-structure 312 is only disposed on the side of the first electrode 210 facing away from the driving substrate 100 and a region where the pixel defining sub-structure 312 is disposed does not exceed a region where the first electrode 210 is located.

The pixel defining sub-structure 312 is disposed on the side of the first electrode 210 facing away from the driving substrate 100. In the preparation of the display panel 10, the first electrode 210 (the reflective electrode 211 and the auxiliary electrode 212) can be subjected to patterned etching by using the pixel defining sub-structure 312, thereby reducing the process preparation cost of the display panel 10. Further, pixel defining sub-structures 312 are disposed on one side of first electrodes 210 of different light-emitting elements 200. Moreover, positions where the pixel defining sub-structures 312 are disposed are considered, and the pixel defining sub-structures 312 on the different light-emitting elements 200 may be understood as independently disposed structures. Independent pixel defining sub-structures 312 can ensure that pixel openings 311 of different light-emitting elements 200 are also independent, thereby avoiding an effect of the deviation of an etching process size on the accuracy of the pixel openings 311, ensuring preparation effects of the pixel openings 311 and further improving the display effect of the display panel 10.

With continued reference to FIG. 3, the display panel 10 further includes a second pixel defining structure 320. The driving substrate 100 includes a planarization layer 105, and the first electrode 210 is located on a side of the planarization layer 105 facing away from the driver circuit 110. The second pixel defining structure 320 covers at least a portion of a surface on a side of the first pixel defining structure 310 facing away from the driving substrate 100 and is in contact with and covers the planarization layer 105 between two adjacent pixel defining sub-structures 312.

Referring to FIG. 3, the display panel 10 further includes the second pixel defining structure 320, the second pixel defining structure 320 includes a portion of structure located on the side of the first pixel defining structure 310 facing away from the driving substrate 100 and further includes a portion of structure located between two adjacent pixel defining sub-structures 312, and the second pixel defining structure 320 located between the two adjacent pixel defining sub-structures 312 is further located on the side of the planarization layer 105 facing away from the driving substrate 100. It may be understood that the second pixel defining structure 320 covers at least a portion of the pixel defining sub-structures 312 and also covers a planarization layer 105 between different light-emitting elements 200.

Referring to FIG. 3, the disposed second pixel defining structure 320 increases a height of the display panel 10 in a thickness direction of the driving substrate 100. Therefore, an extended path of the light-emitting layer 220 in the light-emitting element 200 can be increased. Further, a leakage current between two adjacent light-emitting elements 200 can be reduced, and the display crosstalk between the two adjacent light-emitting elements can be reduced, thereby improving the display effect of the entire display panel 10.

With continued reference to FIG. 3, the first pixel defining structure 310 includes an inorganic pixel defining structure, and the second pixel defining structure 320 includes an organic pixel defining structure.

Further, referring to FIG. 3, the first pixel defining structure 310 may be an inorganic pixel defining structure, or the pixel defining sub-structure 312 may be an inorganic pixel defining structure; the second pixel defining structure 320 may be an organic pixel defining structure. A thickness of a film of the organic pixel defining structure may be larger. In this manner, an organic material is selected as a material of the second pixel defining structure 320, thereby further increasing the extended path of the light-emitting layer 220 in the light-emitting element 200, better reducing a leakage current between two adjacent light-emitting elements 200 and improving the display effect of the entire display panel 10.

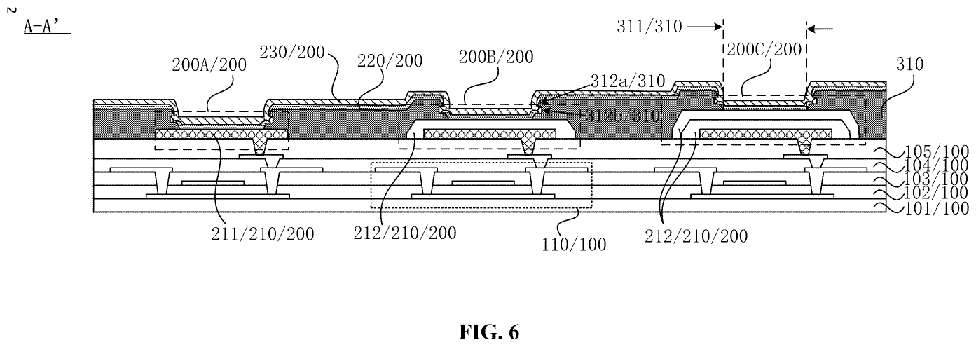

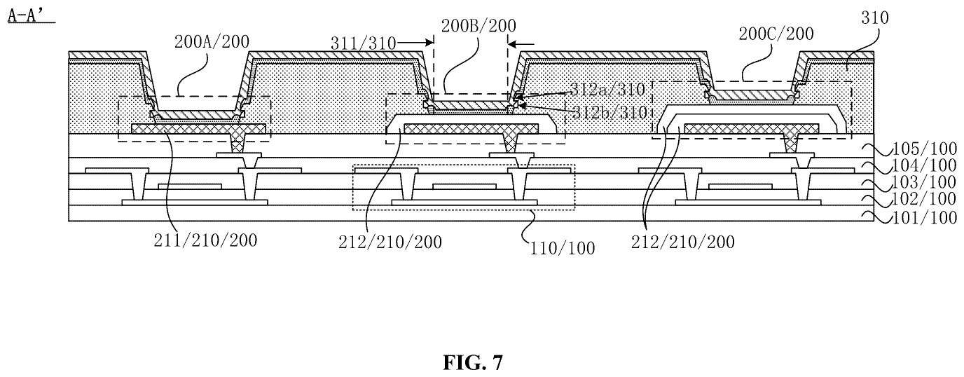

FIG. 6 is a fourth sectional view of FIG. 2 taken along a line A-A′. FIG. 7 is a fifth sectional view of FIG. 2 taken along a line A-A′. Referring to FIGS. 6 and 7, the driving substrate 100 includes a planarization layer 105, where the first electrode 210 is located on a side of the planarization layer 105 facing away from the driver circuit 100. The first pixel defining structure 310 is further in contact with and covers the planarization layer 105 between two adjacent first electrodes 210.

Specifically, referring to FIGS. 6 and 7, the first pixel defining structure 310 includes a portion of structure covering a structure between two adjacent first electrodes 210, and the portion of structure covers the planarization layer 105; the first pixel defining structure 310 further includes a portion of structure on the side of the first electrode 210 facing away from the driving substrate 100. It may be understood that the first pixel defining structure 310 covers a portion of the first electrode 210 and also covers a planarization layer 105 between different light-emitting elements 200.

Further, referring to FIGS. 6 and 7, the first pixel defining structure 310 covers a portion of the first electrode 210 and covers a planarization layer 105 between two adjacent first electrodes 210. A height of a film in a region between the two adjacent first electrodes 210 can be increased by the first pixel defining structure 310, and the flatness of the entire display panel can be improved after the height is increased, thereby facilitating the improvement of a good planarization condition for the preparation of the second electrode 230 and ensuring that the second electrode 230 has good stability.

With continued reference to FIGS. 4 and 5, the display panel 10 further includes a third pixel defining structure 330. The third pixel defining structure 330 is located on a side of the first pixel defining structure 310 facing away from the driving substrate 100 and covers at least a portion of the first pixel defining structure 310.

Further, referring to FIGS. 4 and 5, the display panel 10 further includes the third pixel defining structure 330, and the third pixel defining structure 330 is located on the side of the first pixel defining structure 310 facing away from the driving substrate 100. The third pixel defining structure 330 is disposed so that a thickness of an entire film can be increased, and the extended path of the light-emitting layer 220 in the light-emitting element 200 can be increased after the thickness is increased. Further, a leakage current between two adjacent light-emitting elements 200 can be reduced, and display crosstalk between two adjacent light-emitting elements can be reduced, thereby improving the display effect of the entire display panel 10.

Further, referring to FIGS. 4 and 5, the third pixel defining structure 330 covers at least a portion of the first pixel defining structure 310, and an orthographic projection of the third pixel defining structure 330 on the driving substrate 100 does not overlap an orthographic projection of the pixel opening 111 on the driving substrate 100. The third pixel defining structure 330 does not interfere with the pixel opening 311 and does not block the light emission of the light-emitting element 200. For example, the orthographic projection of the third pixel defining structure 330 on the driving substrate 100 being located between orthographic projections of two reflective electrodes 211 on the driving substrate 100 is used as an example for description in FIG. 4, and the orthographic projection of the third pixel defining structure 330 on the driving substrate 100 partially overlapping the reflective electrode 211 is used as an example for description in FIG. 5. Whether an overlapping region exists between the orthographic projection of the third pixel defining structure 330 on the driving substrate 100 and the orthographic projection of the reflective electrode 211 on the driving substrate 100 may be adaptively adjusted according to different display panels 10, or it may be understood that an area of a region of the first pixel defining structure 310 covered by the third pixel defining structure 330 may be adaptively adjusted according to different display panels 10. These are not limited in the embodiment of the present disclosure.

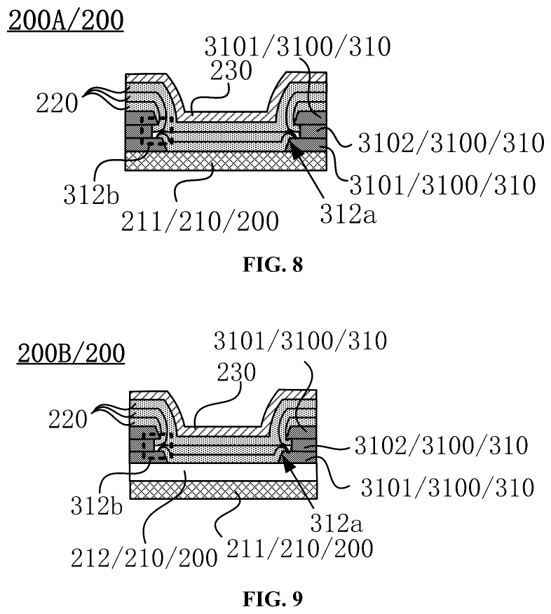

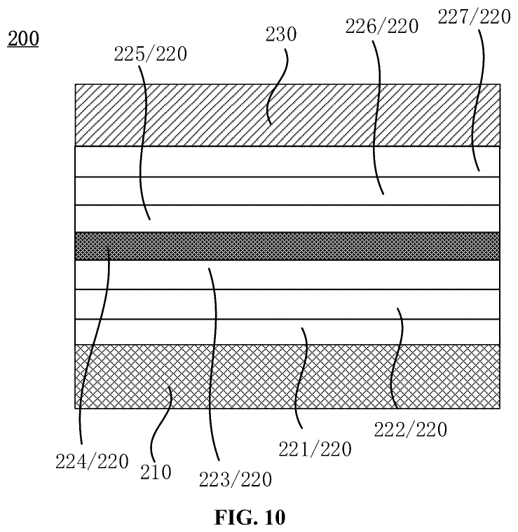

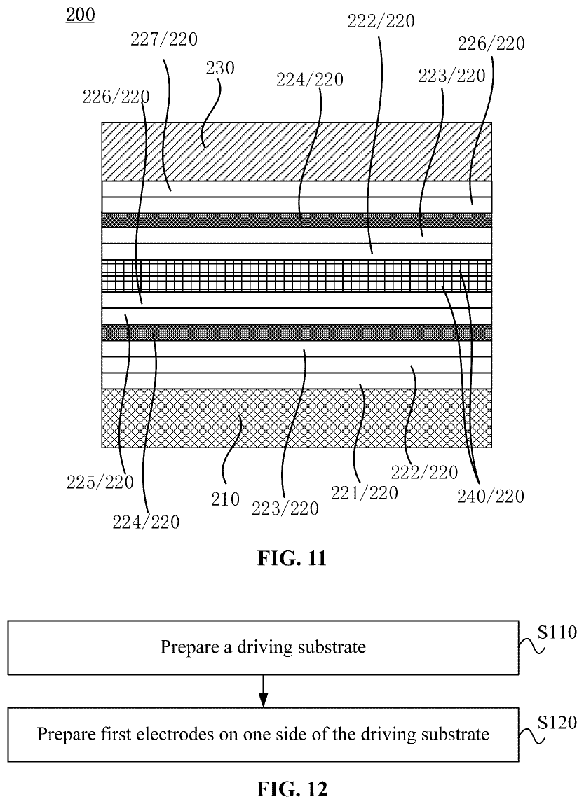

FIG. 8 is an enlarged view of a light-emitting element in FIG. 3. FIG. 9 is an enlarged view of another light-emitting element in FIG. 3. FIG. 10 is a structure diagram of a first light-emitting element according to an embodiment of the present disclosure. FIG. 11 is a structure diagram of a second light-emitting element according to an embodiment of the present disclosure. Referring to FIGS. 3, 4 and 6 to 11, the first pixel defining structure 310 includes a first defining sidewall 312a facing one side of the pixel opening 311, where a first groove 312b is disposed in the first defining sidewall 312a and penetrates through a portion of the first defining sidewall 312a. A light-emitting element 200 further includes multiple light-emitting layers 220 located on the side of the first electrode 210 facing away from the driving substrate 100, where at least one light-emitting layer 220 is disconnected at a position of the first groove 312b.

Further, referring to FIGS. 3, 4, 6 and 7 to 9, the first pixel defining structure 310 includes the first defining sidewall 312a facing the one side of the pixel opening 311, and the first defining sidewall 312a includes the first groove 312b. The first groove 312b is equivalent to a recessed region of the first defining sidewall 312a. The light-emitting element 200 includes a first electrode 210, multiple light-emitting layers 220 and a second electrode 230, and at least one of the multiple light-emitting layers 220 is disconnected at the first groove 312b, thereby avoiding leakage current transmission of holes or electrons between different light-emitting elements 200, further avoiding crosstalk between the different light-emitting elements 200 and ensuring the display effect of the display panel 10.

Optionally, referring to FIG. 10, the light-emitting layers 220 may include multiple films, and along a direction from the first electrode 210 to the second electrode 230, the light-emitting layers 220 may be a hole injection layer (HIL) 221, a hole transport layer (HTL) 222, a compensation layer (Prime) 223, an emission layer (EML) 224, a hole blocking layer (HBL) 225, an electron transport layer (ETL) 226 and an electron injection layer (EIL) 227 in sequence. In correspondence to light-emitting elements 200 of different colors, compensation layers 223 include a red compensation layer (R-Prime), a blue compensation layer (B-Prime) and a green compensation layer (G-Prime). Further, thicknesses of compensation layers of different light-emitting elements 200 are adjusted, thereby further changing cavity lengths of the light-emitting elements 200. Thicknesses of the auxiliary electrode and the compensation layer are adjusted so that the cavity length of microcavity effect is adjusted, thereby ensuring that constructive interference can occur in light emission of different colors in the microcavity and improving the light emission intensity. Specifically, the light emission principle of the light-emitting element 200 may be further understood as follows: a certain voltage is separately applied to the first electrode 210 and the second electrode 230, holes from the first electrode 210 are injected into the hole transport layer 222 via the hole injection layer 221, electrons from the second electrode 230 are injected into the electron transport layer 226 via the electron injection layer 227, the holes and the electrons migrate to the emission layer 224 via the hole transport layer 222 and the electron transport layer 226, respectively, and form excitons in the emission layer 224, and the excitons enable light-emitting molecules in the emission layer 224 to be excited and emit light. The hole blocking layer 225 is used for preventing the holes from entering the electron transport layer 226 via the emission layer 224 so that the holes and the electrons are combined in the emission layer 224 to form the excitons.

Optionally, referring to FIG. 11, the display panel 10 may also be a tandem display panel (a tandem OLED), that is, the light-emitting element 200 is a stacked light-emitting unit, and a display panel 10 using a stacked light-emitting element 200 for light emission is referred to as a tandem display panel, that is, multiple light-emitting layers are connected in series and superimposed by using charge generation layers (CGLs) in the light-emitting element 200 to form the stacked light-emitting element 200. The tandem display panel enables the light-emitting element 200 to be driven at the same current density so that the brightness of the display panel 10 is significantly improved. Specifically, when multiple emission layers 224 are connected in series in the light-emitting element 200 of the tandem display panel, for example, when two emission layers 224 are connected in series, a voltage applied to the second electrode 230 is doubled, the current efficiency is also doubled, and the constant-current lifetime attenuation is consistent. Therefore, a corresponding constant-brightness lifetime is improved by more than one time, the potential in improving the lifetime is larger, and the power consumption also has advantages.

Specifically, when the display panel 10 is a tandem display panel, as shown in FIG. 11, multiple films are stacked in sequence for a design, and charge generation layers 240 that can be electrically connected are disposed between the films. Two charge generation layers 240 are used as an example for illustration in FIG. 11. Further, a structure diagram of a light-emitting element 200 in a tandem display panel 10 is illustrated in FIG. 11. Along a direction from a first electrode 210 to a second electrode 230, film structures may be a hole injection layer 221, a hole transport layer 222, a compensation layer 223, an emission layer 224, a hole blocking layer 225, an electron transport layer 226, two charge generation layers 240, a hole transport layer 222, a compensation layer 223, an emission layer 224, an electron transport layer 226 and an electron injection layer 227 in sequence. The charge generation layers 240 may include a p-type charge generation layer (CGL-P) and an n-type charge generation layer (CGL-N) for generating holes and electrons, respectively, and the emission layer 224 is disposed between the electron transport layer 226 and the hole transport layer 222, that is, a light-emitting layer 220 in the light-emitting element 200 includes at least two emission layers 224. It is to be noted that in FIGS. 10 and 11, the emission layer 224 in the light-emitting element 200 may be a light-emitting layer of red light, a light-emitting layer of blue light or a light-emitting layer of green light and is not specifically limited in the embodiment of the present disclosure. Further, the light-emitting element 200 in the display panel 10 may also include a light-emitting layer of red light, a light-emitting layer of blue light and a light-emitting layer of green light and finally emit white light. For the light-emitting element in the tandem display panel, the thicknesses of the auxiliary electrode and the compensation layer can also be adjusted so that the cavity length of microcavity effect is adjusted, thereby ensuring that constructive interference can occur in light emission of different colors in the microcavity and improving the light emission intensity.

The light-emitting element 200 in the display panel 10 provided in the embodiment of the present disclosure may be the light-emitting element 200 shown in FIG. 10 or the light-emitting element 200 shown in FIG. 11. A specific structure of the light-emitting element 200 is not specifically limited in the embodiment of the present disclosure, and films in a light-emitting unit 500 may be adaptively adjusted according to different actual requirements.

It is to be noted that the case where the light-emitting layer 220 is disconnected at the first groove 312b may be the case where at least some films in the light-emitting layer 220 are disconnected (for example, only the hole injection layer 221 and the hole transport layer 222 are disconnected) or may be the case where the first groove 312b is filled with at least some films in the light-emitting layer 220, which is equivalent to increasing a transmission path. For the specific case where a film in the light-emitting layer 220 is disconnected at the first groove 312b, a process can be adjusted according to different requirements, thereby implementing different disconnections of films.

Referring to FIG. 5, the first pixel defining structure 310 includes an organic pixel defining structure, and the third pixel defining structure 330 includes an inorganic pixel defining structure. The third pixel defining structure 330 covers a surface and a side surface on the side of the first pixel defining structure 310 facing away from the driving substrate 100. The third pixel defining structure 330 includes a second defining sidewall 331a facing one side of the pixel opening 311, where a second groove 331b is disposed in the second defining sidewall 331a and penetrates through a portion of the second defining sidewall 331a.

Further, referring to FIG. 5, the first pixel defining structure 310 includes the organic pixel defining structure, the third pixel defining structure 330 includes the inorganic pixel defining structure, and the third pixel defining structure 330 covers the surface (referring to 310a in FIG. 5) and the side surface (referring to 310b in FIG. 5) of the side of the first pixel defining structure 310 facing away from the driving substrate 100. Further, the third pixel defining structure 330 includes the second defining sidewall 331a facing the one side of the pixel opening 311, and the second groove 331b is disposed in the second defining sidewall 331a. The second groove 331b is equivalent to a recessed region of the second defining sidewall 331a. The light-emitting element 200 includes a first electrode 210, multiple light-emitting layers 220 and a second electrode 230, and at least one of the multiple light-emitting layers 220 is disconnected at the second groove 331b, thereby avoiding leakage current transmission of holes or electrons between different light-emitting elements 200, further avoiding crosstalk between the different light-emitting elements 200 and ensuring the display effect of the display panel 10.

It is to be noted that the case where the light-emitting layer 220 is disconnected at the second groove 331b may be the case where at least some films in the light-emitting layer 220 are disconnected (for example, only the hole injection layer 221 and the hole transport layer 222 are disconnected) or may be the case where the second groove 331b is filled with at least some films in the light-emitting layer 220, which is equivalent to increasing the transmission path. For the specific case where a film in the light-emitting layer 220 is disconnected at the second groove 331b, a process can be adjusted according to different requirements, thereby implementing different disconnections of films.

With continued reference to FIGS. 3 to 5 and 7, the display panel 10 further includes an organic pixel defining structure, and along a thickness direction of the display panel 10, the organic pixel defining structure overlaps a gap between at least two adjacent first electrodes 210. A thickness of the organic pixel defining structure is greater than or equal to a thickness of a first electrode 210.

Further, the display panel 10 includes the organic pixel defining structure, and an orthographic projection of the organic pixel defining structure on the driving substrate 100 overlaps an orthographic projection of a gap between two adjacent first electrodes 210 on the driving substrate 100. Further, the thickness of the organic pixel defining structure is adjusted to be greater than or equal to the thickness of the first electrode 210. The thickness of the organic pixel defining structure is adjusted to be relatively large so that the extended path of the light-emitting layer 220 in the light-emitting element 200 can be increased, thereby further reducing a leakage current between two adjacent light-emitting elements 200, further avoiding crosstalk between different light-emitting elements 200 and improving the display effect of the entire display panel 10.

For example, referring to FIG. 3, the second pixel defining structure 320 in FIG. 3 may be an organic pixel defining structure; referring to FIG. 4, the third pixel defining structure 330 in FIG. 4 may be an organic pixel defining structure; referring to FIG. 5, the first pixel defining structure 310 in FIG. 5 may be an organic pixel defining structure; referring to FIG. 7, the first pixel defining structure 310 in FIG. 7 may be an organic pixel defining structure. For different display panels 10, positions where organic pixel defining structures are disposed can be adjusted to different degrees. However, in the case where the thickness of the organic pixel defining structure is greater than or equal to the thickness of the first electrode 210, the display effect of the entire display panel 10 can be better ensured.

With continued reference to FIGS. 3 to 5 and 7, the light-emitting elements 200 with the different light emission colors include a first light-emitting element and a second light-emitting element. An organic pixel defining structure corresponding to the first light-emitting element and an organic pixel defining structure corresponding to the second light-emitting element have the same thickness.

Further, the display panel 10 includes the first light-emitting element and the second light-emitting element. The first light-emitting element and the second light-emitting element have different emitted colors and may correspond to any two of the light-emitting element 200A, the light-emitting element 200B and the light-emitting element 200C shown in FIGS. 3 to 5 and 7. For example, in conjunction with FIG. 3, using the light-emitting element 200C or the light-emitting element 200B as the first light-emitting element is used as an example, and the organic pixel defining structure corresponding to the first light-emitting element may be understood as a second pixel defining structure 320 overlapping a projection of the light-emitting element 200C on the driving substrate 100 or a second pixel defining structure 320 surrounding at least a portion of the first electrode of the light-emitting element 200C; using the light-emitting element 200A as the second light-emitting element is used as an example, and the organic pixel defining structure corresponding to the second light-emitting element may be understood as a second pixel defining structure 320 overlapping a projection of the light-emitting element 200A on the driving substrate 100 or a second pixel defining structure 320 surrounding at least a portion of the first electrode of the light-emitting element 200C.

Further, organic pixel defining structures corresponding to light-emitting elements 200 of different colors may have the same thickness. In this manner, it can be ensured that the entire display panel 10 has regularity and flatness, and the process preparation difficulty of the display panel 10 can also be reduced. For example, referring to FIGS. 3 to 5 and 7, since a difference exists between the numbers of layers of auxiliary electrodes 212 in the light-emitting element 200A, the light-emitting element 200B and the light-emitting element 200C, the entire light-emitting element 200A, light-emitting element 200B and light-emitting element 200C have different thicknesses. However, a thickness of an organic pixel defining structure disposed between the light-emitting element 200A and the light-emitting element 200B is the same as a thickness of an organic pixel defining structure between the light-emitting element 200B and the light-emitting element 200C, thereby reflecting the regularity of the entire display panel 10.

On the basis of the same inventive concept, an embodiment of the present disclosure further provides a preparation method of a display panel. FIG. 12 is a flowchart of a first preparation method of a display panel according to an embodiment of the present disclosure. Referring to FIG. 12, the preparation method of a display panel includes the steps described below.

In S110, a driving substrate is prepared.

The driving substrate includes a driver circuit, and the driver circuit is electrically connected to light-emitting elements prepared subsequently. The driver circuit can provide a drive current for the light-emitting elements to drive the light-emitting elements to perform light-emitting display, thereby implementing a display function of the display panel. Further, the driver circuit in the driving substrate may include a transistor, and the transistor may include an active layer, a gate, a source and a drain. Moreover, the driver circuit is disposed in diverse manners and may be, for example, “7T1C” or “8T2C”, where “T” denotes a transistor, and “C” denotes a capacitor. A specific manner of disposing the driver circuit in the driving substrate may be adaptively adjusted according to different display panels and is not specifically limited in the embodiment of the present disclosure.

Further, the driving substrate may include a substrate, a gate insulating layer, a first interlayer insulating layer, a second interlayer insulating layer and a planarization layer, and the gate insulating layer, the first interlayer insulating layer, the second interlayer insulating layer and the planarization layer may be disposed between two adjacent metal layers to play a role in signal isolation and planarization.

In S120, first electrodes are prepared on one side of the driving substrate.

Further, multiple light-emitting elements are prepared on one side of the driving substrate, and the driver circuit in the driving substrate is electrically connected to the light-emitting elements. The driver circuit can provide a drive current for the light-emitting elements to drive the light-emitting elements to perform light-emitting display, thereby implementing a display function of the display panel.

Specifically, the light-emitting element includes the first electrode and is electrically connected to the driver circuit via the first electrode. In other words, the drive current provided by the driver circuit is transmitted to the light-emitting element via the first electrode. Further, the light-emitting element further includes a light-emitting layer and a second electrode, and the light-emitting layer is located between the first electrode and the second electrode. A light emission principle of the light-emitting element may be understood as follows: a certain electric signal is separately applied to the first electrode and the second electrode, and holes from the first electrode and electrons from the second electrode converge in the light-emitting layer and are further excited in the light-emitting layer to emit light, thereby implementing the light emission of the light-emitting element.

Further, the second electrode may be a semi-transmissive and semi-reflective electrode. Excited in the light-emitting layer, emitted light can be reflected for multiple times in a microcavity formed by the reflective electrode and the second electrode, and constructive interference occurs in light with a particular wavelength, thereby enhancing light intensity. Constructive interference occurs when a distance between the first electrode and the second electrode is integer times a wavelength of transmitted light. The relational expression is as follows:

d=n*(λ/2)

where d denotes a distance between the reflective electrode 211 and the second electrode 230.

As can be seen from the above relational expression, to ensure constructive interference, it needs to be ensured that the distance between the reflective electrode and the second electrode satisfies integer times the wavelength, that is, a distance between a reflective electrode and a second electrode in a light-emitting element with a long emission wavelength needs to be long. Therefore, in the embodiment of the present disclosure, a thickness of the auxiliary electrode is adjusted so that the distance between the reflective electrode and the second electrode is adjusted. Specifically, auxiliary electrodes in light-emitting elements with different light emission colors have different thicknesses. Specifically, in a light-emitting element with a relatively long light emission wavelength, an auxiliary electrode has a relatively large thickness, and in a light-emitting element with a relatively short light emission wavelength, an auxiliary electrode has a relatively small thickness. The thickness of the auxiliary electrode is adjusted so that a cavity length of microcavity effect is adjusted, thereby ensuring that constructive interference can occur in light emission of different colors in the microcavity and improving light emission intensity.

Further, at least some first electrodes further include auxiliary electrodes, and thicknesses of auxiliary electrodes in light-emitting elements of different colors may be set differently. The auxiliary electrode is disposed, and thicknesses of auxiliary electrodes in light-emitting elements of different colors are adjusted to be different, thereby implementing different gaps between reflective electrodes and second electrodes in the light-emitting elements of the different colors.

For example, a wavelength of a red light-emitting element is longer than a wavelength of a green light-emitting element, and a thickness of an auxiliary electrode in the red light-emitting element may be adjusted to be greater than a thickness of an auxiliary electrode in the green light-emitting element; the wavelength of the green light-emitting element is longer than a wavelength of a blue light-emitting element, and the thickness of the auxiliary electrode in the green light-emitting element may be adjusted to be greater than a thickness of an auxiliary electrode in the blue light-emitting element.

In conclusion, according to the preparation method of a display panel provided in the embodiment of the present disclosure, auxiliary electrodes of light-emitting elements of different colors are set differently. Thicknesses of the auxiliary electrodes of the light-emitting elements of the different colors are adjusted so that the cavity length of microcavity effect is adjusted and light emission effects of the light-emitting elements of the different colors are adjusted, thereby ensuring a display effect of the display panel.

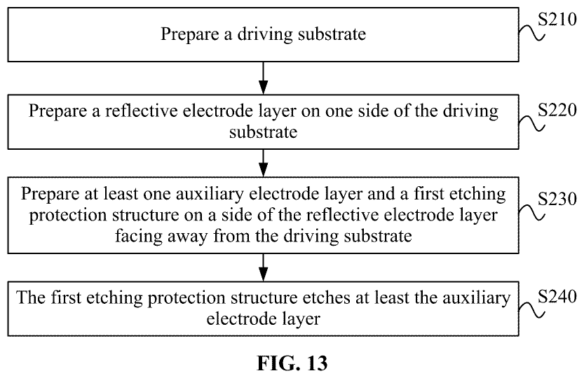

FIG. 13 is a flowchart of a second preparation method of a display panel according to an embodiment of the present disclosure. Referring to FIG. 13, the preparation method further includes the steps described below.

In S210, a driving substrate is prepared.

In S220, a reflective electrode layer is prepared on one side of the driving substrate.

The reflective electrode layer is prepared on the one side of the driving substrate. The reflective electrode layer is a metal layer that can reflect light. The reflective electrode layer is subjected to pattern etching through a subsequent process, and a corresponding reflective electrode can be formed.

In S230, at least one auxiliary electrode layer and a first etching protection structure are prepared on a side of the reflective electrode layer facing away from the driving substrate.

Further, the at least one auxiliary electrode layer is prepared on the side of the reflective electrode layer facing away from the substrate. The number of specifically disposed auxiliary electrode layers may be differently set according to light-emitting elements that need to be formed subsequently. For example, after patterned etching, the reflective electrode layer corresponds to a reflective electrode of the red light-emitting element, and two or more auxiliary electrode layers can be prepared at the corresponding reflective electrode layer. For example, after patterned etching, the reflective electrode layer corresponds to a reflective electrode of the green light-emitting element, and one auxiliary electrode layer can be prepared at the corresponding reflective electrode layer. For example, after patterned etching, the reflective electrode layer corresponds to a reflective electrode of the blue light-emitting element, and no auxiliary electrode layer can be prepared at the corresponding reflective electrode layer. The numbers of disposed auxiliary electrode layers may be differently set according to different display panels and light-emitting elements of different colors in a display panel, and the specific number of layers of auxiliary electrodes may be adaptively increased or decreased according to an actual requirement. These are not limited in the embodiment of the present disclosure.

In S240, at least the auxiliary electrode layer is etched by the first etching protection structure.

Further, the first etching protection structure is prepared on the side of the reflective electrode layer facing away from the driving substrate so that the auxiliary electrode layer can be etched by the first etching protection structure. Specifically, in a region where the first etching protection structure is disposed, the auxiliary electrode layer is protected instead of being etched, and a corresponding auxiliary electrode is formed; in a region where no first etching protection structure is disposed, the auxiliary electrode layer is etched and removed, thereby implementing the patterned etching of the auxiliary electrode layer. Further, other film structures such as the reflective electrode layer may also be etched and removed by the first etching protection structure. The auxiliary electrode layer and the reflective electrode layer can be synchronously subjected to patterned etching by using the first etching protection structure, thereby reducing a process preparation cost of the display panel.

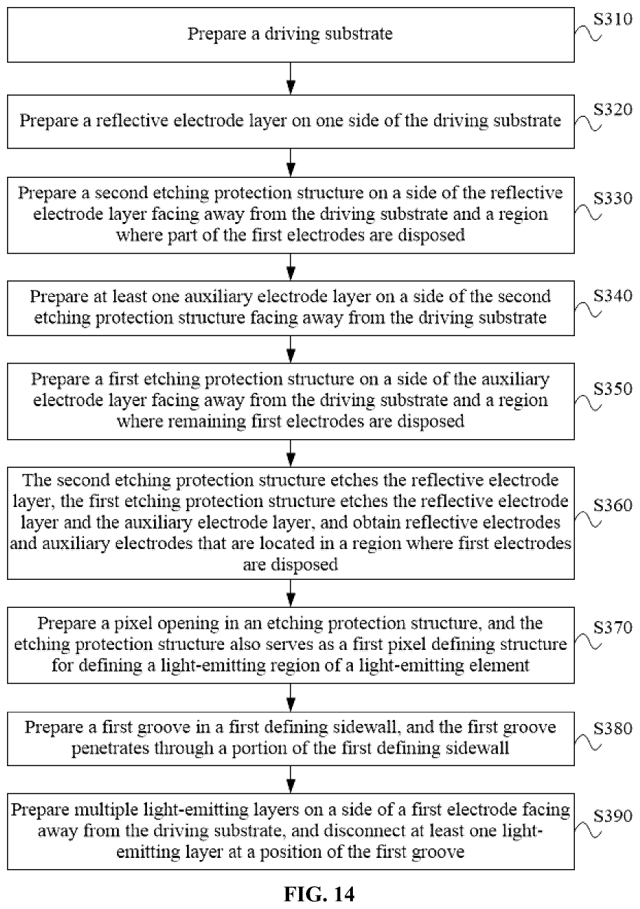

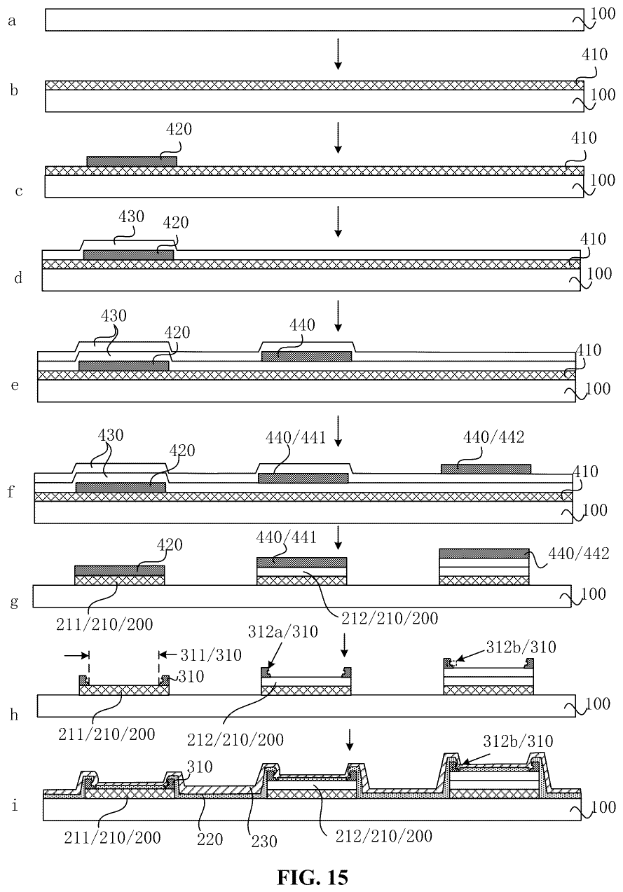

FIG. 14 is a flowchart of a third preparation method of a display panel according to an embodiment of the present disclosure. FIG. 15 is a schematic diagram of a first preparation process of a display panel according to an embodiment of the present disclosure. Referring to FIGS. 14 and 15, the preparation method further includes the steps described below.

In S310, a driving substrate is prepared.

Specifically, referring to step a in FIG. 15, a driving substrate 100 is prepared.

In S320, a reflective electrode layer is prepared on one side of the driving substrate.

Specifically, referring to step b in FIG. 15, a reflective electrode layer 410 is prepared on one side of the driving substrate 100.

In S330, a second etching protection structure is prepared on a side of the reflective electrode layer facing away from the driving substrate and a region where part of first electrodes are disposed.

Specifically, referring to step c in FIG. 15, a second etching protection structure 420 is disposed on a side of the reflective electrode layer 410 facing away from the driving substrate 100. The second etching protection structure 420 is not laid over an entire surface. The reflective electrode layer 410 is subsequently subjected to patterned etching to form multiple reflective electrodes, and a region of the reflective electrode layer 410 where first electrodes are subsequently formed through etching may be understood as a region where the first electrodes are disposed. Further, the second etching protection structure 420 is disposed in a portion of the region where the first electrode is disposed, and a remaining reflective electrode layer can be subsequently removed by the second etching protection structure 420.

In S340, at least one auxiliary electrode layer is prepared on a side of the second etching protection structure facing away from the driving substrate.

Specifically, referring to step d in FIG. 15, at least one auxiliary electrode layer 430 is prepared on a side of the second etching protection structure 420 facing away from the driving substrate 100, and a material of the auxiliary electrode layer 430 may be indium tin oxide or another transparent conductive material. The auxiliary electrode layer 430 is subsequently subjected to patterned etching, and an auxiliary electrode 212 can be formed. The numbers of auxiliary electrode layers 430 are set differently so that a difference in the numbers of layers of auxiliary electrodes 212 in different light-emitting elements is implemented and gaps between reflective electrodes 211 and subsequently prepared second electrodes 230 can be set differently.

In S350, a first etching protection structure is prepared on a side of the auxiliary electrode layer facing away from the driving substrate and a region where remaining first electrodes are disposed.

Specifically, referring to step e in FIG. 15, a first etching protection structure 440 is prepared on a side of the auxiliary electrode layer 430 facing away from the driving substrate 100 and a region where remaining first electrodes are disposed. The region where the remaining first electrodes are disposed may be understood as a region where no second etching protection structure 420 is disposed and part of first electrodes are disposed.

Further, referring to step e in FIG. 15, the auxiliary electrode layer 430 covers the second etching protection structure 420, and one auxiliary electrode layer 430 may be further disposed on a side of the first etching protection structure 440 (referring to a first etching protection structure 441 in the figure) facing away from the driving substrate 100. Referring to step f in FIG. 15, a first etching protection structure 440 (referring to a first etching protection structure 442 in the figure) is further disposed at a position facing away from the auxiliary electrode layer 430 and the region where the remaining first electrodes are disposed. In this manner, no auxiliary electrode layer 430 exists between the second etching protection structure 440 and the reflective electrode layer 410, one auxiliary electrode layer 430 exists between the first etching protection structure 441 and the reflective electrode layer 410, and two auxiliary electrode layers 430 exist between the first etching protection structure 442 and the reflective electrode layer 410 so that different numbers of auxiliary electrode layers 430 exist between different regions where first electrodes are located and corresponding etching protection structures.

In S360, the reflective electrode layer is etched by the second etching protection structure, the reflective electrode layer and the auxiliary electrode layer are etched by the first etching protection structure, and reflective electrodes and auxiliary electrodes that are located in a region where first electrodes are disposed are obtained.

Further, referring to step g in FIG. 15, an auxiliary electrode layer 430 where no first etching protection structure 440 is disposed can be removed by the first etching protection structure 440, thereby remaining an auxiliary electrode layer 430 with a first etching protection structure 440 facing the driving substrate 100 to form auxiliary electrodes 212. Correspondingly, one layer of auxiliary electrodes 212 exists between the first etching protection structure 441 and the driving substrate 100, and two layers of auxiliary electrodes 212 exist between the first etching protection structure 442 and the driving substrate 100.

Further, a reflective electrode layer 410 where no etching protection structure is disposed is removed by the second etching protection structure 420 and the first etching protection structure 440, thereby remaining a reflective electrode layer 410 with a first etching protection structure 440 facing the driving substrate 100 and a reflective electrode layer 410 with a second etching protection structure 420 facing the driving substrate 100 to form corresponding reflective electrodes 211.

Correspondingly, the preparation of first electrodes 210 in light-emitting elements is completed through the preparation of the auxiliary electrodes 212 and the reflective electrodes 211. The auxiliary electrodes 212 and the reflective electrodes 211 in the first electrodes 210 can be synchronously prepared by the second etching protection structure 420 and the first etching protection structure 440. Further, since the auxiliary electrodes 212 and the reflective electrodes 211 are prepared synchronously, the auxiliary electrodes 212 and the reflective electrodes 211 have the same or similar size. An area of space occupied by the light-emitting element 200 in the display panel 10 is not increased due to an increase in the number of disposed auxiliary electrodes 212 in the light-emitting element 200. It is conducive to disposing the display panel 10 in a manner with a high pixel density and improving a display effect of the entire display panel 10. Further, when sizes of multiple layers of auxiliary electrodes 212 additionally disposed in the light-emitting element 200 are the same or similar, the regularity of the entire light-emitting element 200 can also be ensured, and the multiple layers of auxiliary electrodes 212 can also be prepared by using the same etching protective layer, thereby reducing the process preparation difficulty of the display panel 10 and reducing the process preparation cost of the display panel 10.

The reflective electrode layer 410 and the auxiliary electrode layer 430 can be synchronously etched and removed by the first etching protection structure 440, and the auxiliary electrode layer 430 can be etched and removed by the second etching protection structure 420.

In S370, a pixel opening is prepared in an etching protection structure, and the etching protection structure also serves as a first pixel defining structure for defining a light-emitting region of a light-emitting element.

Further, referring to step g and step h in FIG. 15, the etching protection structure includes the first etching protection structure 440 and the second etching protection structure 420. The first etching protection structure 440 and the second etching protection structure 420 may also serve as first pixel defining structures 310, and the first pixel defining structures 310 are subjected to opening and etching to form corresponding pixel openings 311. Specifically, the pixel opening 311 may be understood as a hollowed-out area of the first pixel defining structure 310 or may be understood as an opening region formed after the first pixel defining structure 310 is subjected to patterned etching.

In S380, a first groove is prepared in a first defining sidewall and penetrates through a portion of the first defining sidewall.

With continued reference to step h in FIG. 15 and referring to FIGS. 8 and 9, the first pixel defining structure 310 includes a first defining sidewall 312a facing one side of the pixel opening 311, and the first defining sidewall 312a includes a first groove 312b. The first groove 312b is equivalent to a recessed region of the first defining sidewall 312a. Optionally, the first groove may be synchronously prepared while the pixel opening is prepared; or the etching protection structure may also be etched first to prepare the pixel opening, and then the first groove is prepared in the first defining sidewall.

In S390, multiple light-emitting layers are prepared on a side of a first electrode facing away from the driving substrate, and at least one light-emitting layer is disconnected at a position of the first groove.

Referring to step i in FIG. 15, the light-emitting element 200 includes a first electrode 210, multiple light-emitting layers 220 and a second electrode 230, and at least one of the multiple light-emitting layers 220 is disconnected at the first groove 312b, thereby avoiding leakage current transmission of holes or electrons between different light-emitting elements 200, further avoiding crosstalk between the different light-emitting elements 200 and ensuring the display effect of the display panel 10. To clearly see the disconnection of the light-emitting layer, reference may be made to FIGS. 8 and 9, at least different layers among the multiple light-emitting layers 220 are disconnected at the first groove 312b.

Further, referring to FIGS. 8 and 9, the first pixel defining structure 310 includes multiple stacked defining films 3100, and two adjacent defining films are made of different materials.

Further, referring to FIGS. 8 and 9, the first pixel defining structure 310 includes multiple stacked defining films 3100, and two adjacent defining films 3100 are made of different materials. For example, a material of a defining film 3101 is silicon oxide, and a material of a defining film 3102 is silicon nitride. Different materials are used for the preparation of films. During etching, considering that different materials have different etching rates, under the same etching condition, the first groove 312b can be formed due to the case where the etching degree of the defining film 3101 is less than the etching degree of the defining film 3102.

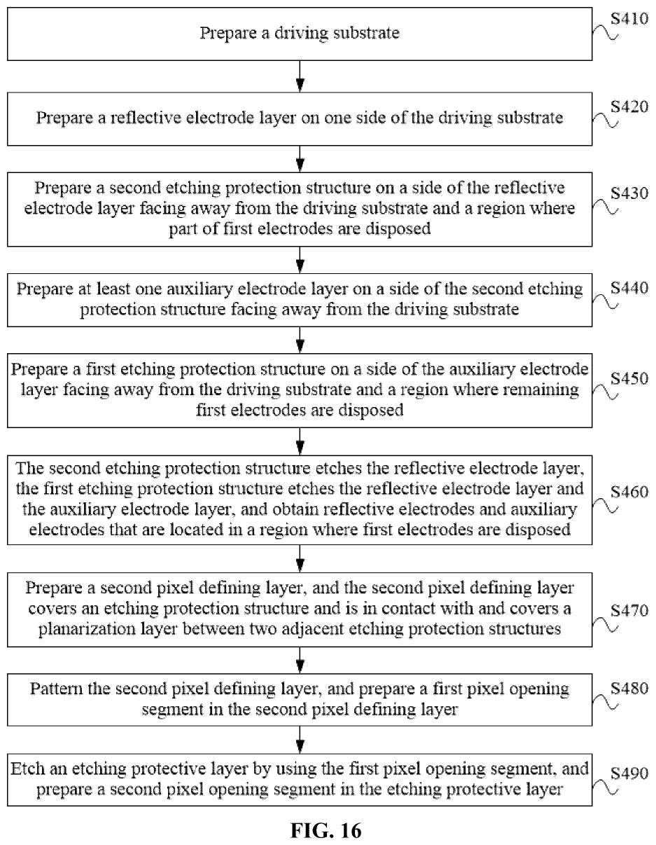

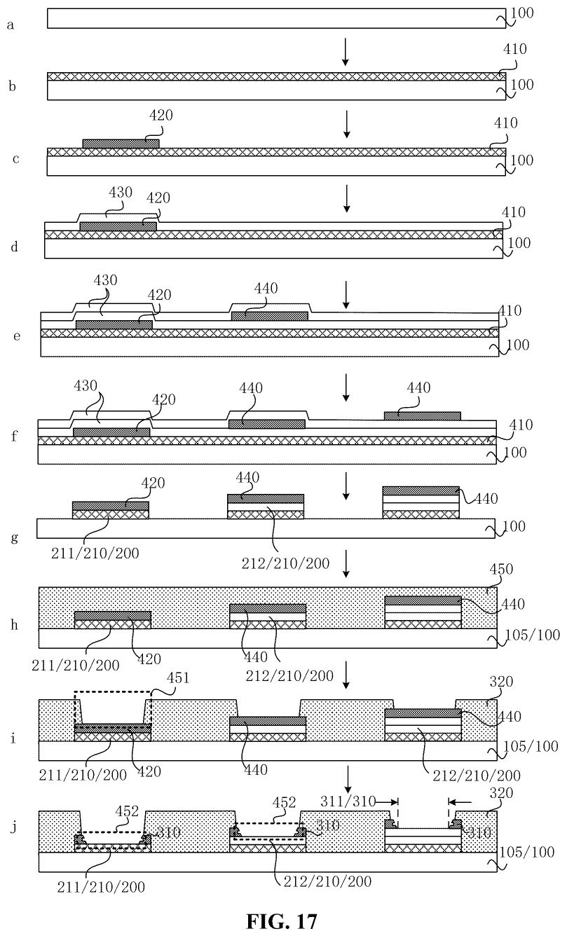

FIG. 16 is a flowchart of a fourth preparation method of a display panel according to an embodiment of the present disclosure. FIG. 17 is a schematic diagram of a second preparation process of a display panel according to an embodiment of the present disclosure. Referring to FIGS. 16 and 17, the preparation method of a display panel further includes the steps described below.

In S410, a driving substrate is prepared.

Specifically, referring to step a in FIG. 17, a driving substrate 100 is prepared.

In S420, a reflective electrode layer is prepared on one side of the driving substrate.

Specifically, referring to step b in FIG. 17, a reflective electrode layer 410 is prepared on one side of the driving substrate 100.

In S430, a second etching protection structure is prepared on a side of the reflective electrode layer facing away from the driving substrate and a region where part of first electrodes are disposed.

Specifically, referring to step e in FIG. 17, a second etching protection structure 420 is prepared on a side of the reflective electrode layer 410 facing away from the driving substrate 100 and a region where part of first electrodes are disposed.

In S440, at least one auxiliary electrode layer is prepared on a side of the second etching protection structure facing away from the driving substrate.

Specifically, referring to step d in FIG. 17, at least one auxiliary electrode layer 430 is prepared on a side of the second etching protection structure 420 facing away from the driving substrate 100.

In S450, a first etching protection structure is prepared on a side of the auxiliary electrode layer facing away from the driving substrate and a region where remaining first electrodes are disposed.

Specifically, referring to step e and step f in FIG. 17, a first etching protection structure 440 is prepared on a side of the auxiliary electrode layer 420 facing away from the driving substrate 100 and a region where remaining first electrodes are disposed.

In S460, the reflective electrode layer is etched by the second etching protection structure, the reflective electrode layer and the auxiliary electrode layer are etched by the first etching protection structure, and reflective electrodes and auxiliary electrodes that are located in a region where first electrodes are disposed are obtained.

Specifically, referring to step g in FIG. 17, the reflective electrode layer 410 is etched by the second etching protection structure 440, the reflective electrode layer 410 and the auxiliary electrode layer 430 are etched by the first etching protection structure 420, and reflective electrodes 211 and auxiliary electrodes 212 that are located in a region where first electrodes are disposed are obtained.

In S470, a second pixel defining layer is prepared, and the second pixel defining layer covers an etching protection structure and is in contact with and covers a planarization layer between two adjacent etching protection structures.

Specifically, referring to step h in FIG. 17, a second pixel defining layer 450 is prepared, and the second pixel defining layer 450 completely covers the first etching protection structure 440, the second etching protection structure 420 and a planarization layer 105 between the first etching protection structure 440 and the second etching protection structure 420.

In S480, the second pixel defining layer is patterned, and a first pixel opening segment is prepared in the second pixel defining layer.

Specifically, referring to step i in FIG. 17, the second pixel defining layer 450 is subjected to patterned etching, and a first pixel opening segment 451 is prepared. The first pixel opening segment 451 exposes a portion of the first etching protection structure 440 and also exposes a portion of the second etching protection structure 420.

In S490, an etching protective layer is etched by using the first pixel opening segment, and a second pixel opening segment is prepared in the etching protective layer.

Specifically, referring to step j in FIG. 17, an etching protective layer is etched. Specifically, the exposed second etching protection structure 420 and first etching protection structure 440 are etched by using the first pixel opening 451 to form a second pixel opening segment 452. The first electrode 210 is exposed by the first pixel opening segment 451 and the second pixel opening segment 452, and an exposed portion of the first electrode 210 may be understood as the pixel opening 311.

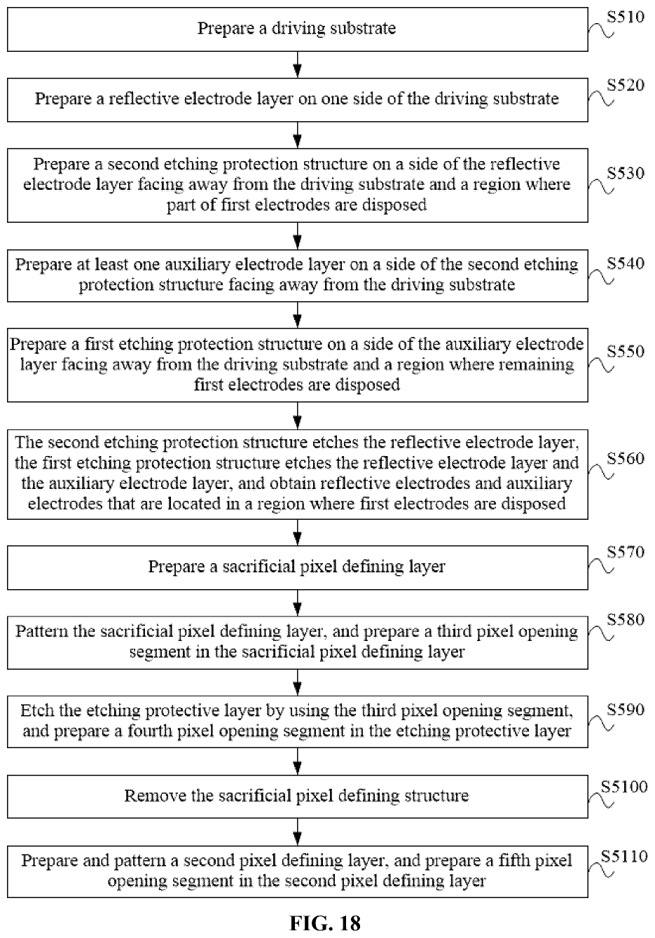

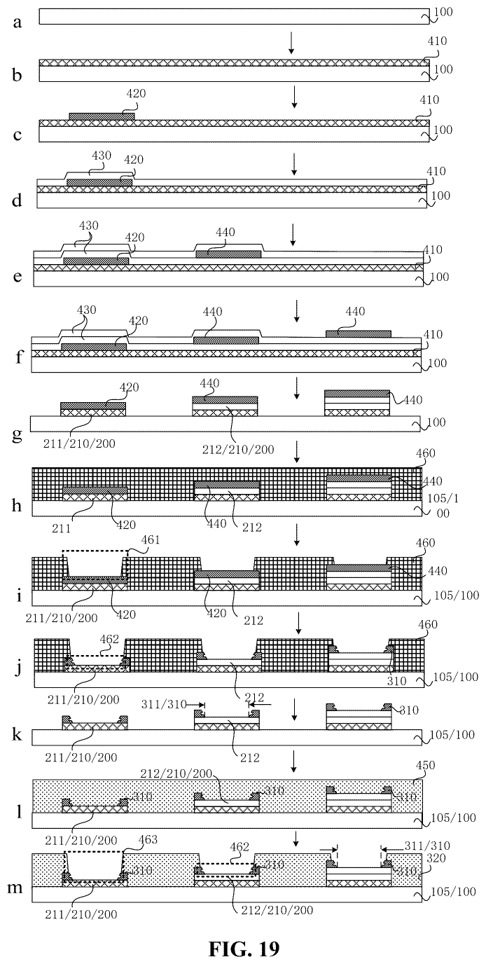

FIG. 18 is a flowchart of a fifth preparation method of a display panel according to an embodiment of the present disclosure. FIG. 19 is a schematic diagram of a third preparation process of a display panel according to an embodiment of the present disclosure. Referring to FIGS. 18 and 19, the preparation method further includes the steps described below.

In S510, a driving substrate is prepared.

Specifically, referring to step a in FIG. 19, a driving substrate 100 is prepared.

In S520, a reflective electrode layer is prepared on one side of the driving substrate.

Specifically, referring to step b in FIG. 19, a reflective electrode layer 410 is prepared on the driving substrate 100.

In S530, a second etching protection structure is prepared on a side of the reflective electrode layer facing away from the driving substrate and a region where part of first electrodes are disposed.

Specifically, referring to step c in FIG. 19, a second etching protection structure 420 is prepared on a side of the reflective electrode layer 410 facing away from the driving substrate 100 and a region where part of first electrodes are disposed.

In S540, at least one auxiliary electrode layer is prepared on a side of the second etching protection structure facing away from the driving substrate.

Specifically, referring to step d in FIG. 19, at least one auxiliary electrode layer 430 is prepared on a side of the second etching protection structure 420 facing away from the driving substrate 100.

In S550, a first etching protection structure is prepared on a side of the auxiliary electrode layer facing away from the driving substrate and a region where remaining first electrodes are disposed.

Specifically, referring to step e and step f in FIG. 19, a first etching protection structure 440 is prepared on a side of the auxiliary electrode layer 420 facing away from the driving substrate 100 and a region where remaining first electrodes are disposed.

In S560, the reflective electrode layer is etched by the second etching protection structure, the reflective electrode layer and the auxiliary electrode layer are etched by the first etching protection structure, and reflective electrodes and auxiliary electrodes that are located in a region where first electrodes are disposed are obtained.

Specifically, referring to step g in FIG. 19, the reflective electrode layer 410 is etched by the second etching protection structure 440, the reflective electrode layer 410 and the auxiliary electrode layer 430 are etched by the first etching protection structure 420, and reflective electrodes 211 and auxiliary electrodes 212 that are located in a region where first electrodes are disposed are obtained.

In S570, a sacrificial pixel defining layer is prepared.

Specifically, referring to step h in FIG. 19, a sacrificial pixel defining layer 460 is prepared. The sacrificial pixel defining layer 460 completely covers the first etching protection structure 440, the second etching protection structure 420 and the planarization layer 105 between the first etching protection structure 440 and the second etching protection structure 420.

In S580, the sacrificial pixel defining layer is patterned, and a third pixel opening segment is prepared in the sacrificial pixel defining layer.

Specifically, referring to step i in FIG. 19, the sacrificial pixel defining layer 460 is subjected to patterned etching, and a third pixel opening segment 461 is prepared. The third pixel opening segment 461 exposes a portion of the first etching protection structure 440 and also exposes a portion of the second etching protection structure 420.

In S590, the etching protective layer is etched by using the third pixel opening segment, and a fourth pixel opening segment is prepared in the etching protective layer.

Specifically, referring to step j in FIG. 17, an etching protective layer is etched. Specifically, the exposed second etching protection structure 420 and first etching protection structure 440 are etched by using the third pixel opening segment 461 to form a fourth pixel opening segment 462. The first electrode 210 is exposed by the third pixel opening segment 461 and the fourth pixel opening segment 462, and an exposed portion of the first electrode 210 may be understood as the pixel opening 311.

In S5100, the sacrificial pixel defining structure is removed.

Specifically, referring to step k in FIG. 19, a remaining sacrificial pixel defining structure 450 is removed.

In S5110, a second pixel defining layer is prepared and patterned, and a fifth pixel opening segment is prepared in the second pixel defining layer.

Specifically, referring to step 1 in FIG. 19, a second pixel defining layer 450 is prepared and laid over an entire surface. Further, referring to step m in FIG. 10, the second pixel defining layer 450 is subjected to patterned etching to form a fifth pixel opening segment 463. The fifth pixel opening segment 463 penetrates through the second pixel defining layer 450 on a side of the first electrode 210 facing away from the driving substrate 100 to obtain a second pixel defining structure 320, and the pixel opening 311 includes the fourth pixel opening segment 462 and the fifth pixel opening segment 463.

Compared with the case where an opening is prepared for an etching protection structure in an opening region of the second pixel definition layer, the case where an opening is prepared for the etching protection structure in an opening region of the sacrificial pixel definition structure can avoid affecting the second pixel definition structure during the opening process of the etching protection structure and can also ensure the stability of each structure in the display panel while ensuring better morphology of the pixel opening.

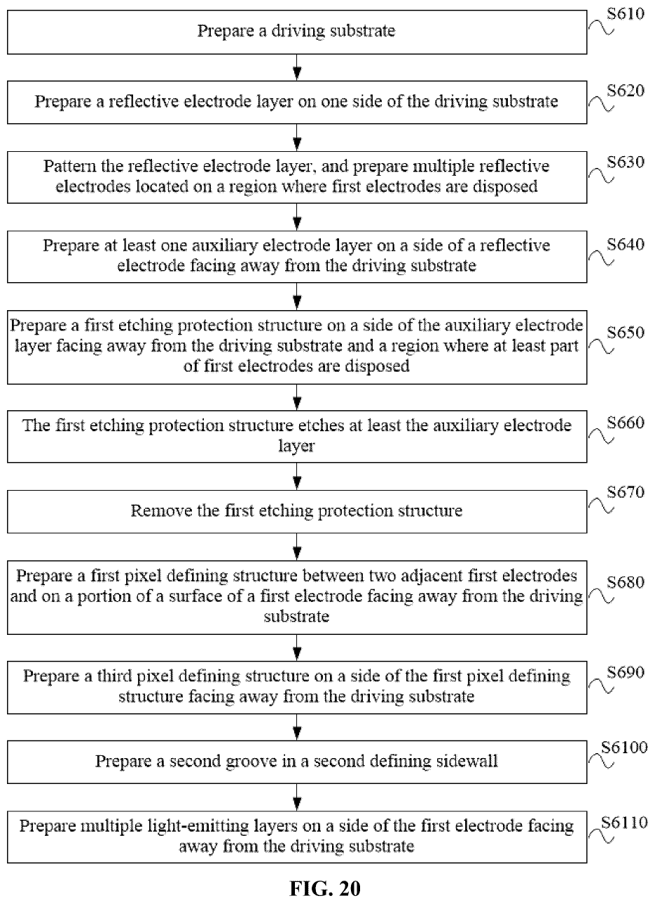

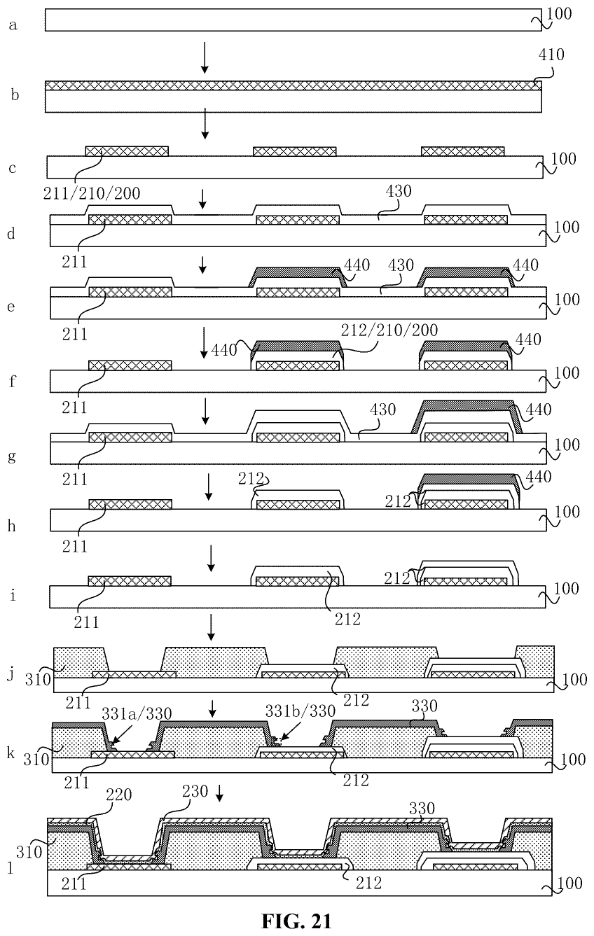

FIG. 20 is a flowchart of a sixth preparation method of a display panel according to an embodiment of the present disclosure. FIG. 21 is a schematic diagram of a seventh preparation process of a display panel according to an embodiment of the present disclosure. Referring to FIGS. 20 and 21, the preparation method of a display panel further includes the steps described below.

In S610, a driving substrate is prepared.

Specifically, referring to step a in FIG. 21, a driving substrate 100 is prepared.

In S620, a reflective electrode layer is prepared on one side of the driving substrate.

Specifically, referring to step b in FIG. 21, a reflective electrode layer 410 is prepared on one side of the driving substrate 100.

In S630, the reflective electrode layer is patterned, and multiple reflective electrodes located on a region where first electrodes are disposed are prepared.

Specifically, referring to step c in FIG. 21, the reflective electrode layer 410 is subjected to patterned etching, thereby preparing multiple reflective electrodes 211. A region where the reflective electrodes 211 are disposed may be understood as a region where first electrodes 210 are disposed.

In S640, at least one auxiliary electrode layer is prepared on a side of a reflective electrode facing away from the driving substrate.

Specifically, referring to step d in FIG. 21, at least one auxiliary electrode layer 430 is prepared on a side of a reflective electrode 211 facing away from the driving substrate 100. One auxiliary electrode layer 430 being prepared on the side of the reflective electrode 211 facing away from the driving substrate 100 is illustrated in step d in FIG. 21. The specific number of disposed auxiliary electrode layers 430 may be adaptively adjusted according to a requirement and is not specifically limited in the embodiment of the present disclosure.

In S650, a first etching protection structure is prepared on a side of the auxiliary electrode layer facing away from the driving substrate and a region where at least part of first electrodes are disposed.

Specifically, referring to step e in FIG. 21, a first etching protection structure 440 is disposed in a region where at least part of first electrodes are disposed and a side of the auxiliary electrode layer 430 facing away from the driving substrate 100. Subsequently, the reflective electrode layer 410 can be subjected to patterned etching by the first etching protection structure 440. It may be understood that in the region where the first electrodes are disposed, the first etching protection structure 440 is disposed and an auxiliary electrode layer 430 between the first etching protection structure 440 and the driving substrate 100 can remain, and in the region where the first electrodes are disposed, no first etching protection structure 440 is disposed, a corresponding auxiliary electrode layer 430 is removed in a subsequent etching process.

In S660, at least the auxiliary electrode layer is etched by the first etching protection structure.

Specifically, referring to step fin FIG. 21, for the auxiliary electrode layer 430, a region not covered by the first etching protection structure 440 is removed, and a region covered by the first etching protection structure 440 remains. An auxiliary electrode layer 430 remaining through etching is an auxiliary electrode 212. Referring to step f to step h in FIG. 21, different numbers of auxiliary electrode layers 430 may be disposed in different regions where first electrodes are disposed, and the first etching protection structure 440 may be prepared for multiple times, thereby implementing different numbers of layers of auxiliary electrodes 212 in the regions where the first electrodes are disposed, as shown in step g in FIG. 21.

Further, the auxiliary electrode 212 is prepared step by step so that the auxiliary electrode 212 can cover the reflective electrode 211, and among adjacent auxiliary electrodes 212, an auxiliary electrode 212 facing away from a side of the driving substrate 100 can cover an auxiliary electrode 212 facing the side of the driving substrate 100. Contact areas between the auxiliary electrode 212 and other films can be ensured, and the auxiliary electrode 212 being stably disposed on the side of the reflective electrode 211 facing away from the driving substrate 100 is ensured. It may be understood that a size of the auxiliary electrode 212 is adjusted to ensure the result stability of the auxiliary electrode 212.

In S670, the first etching protection structure is removed.

Specifically, referring to step i in FIG. 21, the first etching protection structure 440 is removed, and the reflective electrode 211 and the auxiliary electrode 212 remain on one side of the driving substrate 100.

In S680, a first pixel defining structure is prepared between two adjacent first electrodes and on a portion of a surface of a first electrode facing away from the driving substrate.

Specifically, referring to step j in FIG. 21, a first pixel defining structure 310 is prepared. The first pixel defining structure 310 covers a portion of a surface on a side of a first electrode 210 facing away from the driving substrate 100 and covers a planarization layer 105 between two adjacent first electrodes 210. The first pixel defining structure 310 may be made of an organic material. The first pixel defining structure 310 raises a region between two adjacent first electrodes 210 so that a transmission path of a light-emitting layer can be increased when the light-emitting layer is subsequently prepared, thereby further reducing a leakage current between two adjacent light-emitting elements, ensuring light emission effects of the light-emitting elements and improving a display effect of the entire display panel 10.

In S690, a third pixel defining structure is prepared on a side of the first pixel defining structure facing away from the driving substrate.

Specifically, referring to step k in FIG. 21, a third pixel defining structure 330 is disposed on a side of the first pixel defining structure 310 facing away from the driving substrate 310. The third pixel defining structure 330 is disposed so that a thickness of an entire film can also be increased, and an extended path of a light-emitting layer 220 in a light-emitting element can be increased after the thickness is increased. Further, a leakage current between two adjacent light-emitting elements can be reduced, and light emission effects of the light-emitting elements 200 can be ensured, thereby improving the display effect of the entire display panel 10.

Further, the third pixel defining structure 330 can also cover a surface and a side surface on the side of the first pixel defining structure 310 facing away from the driving substrate 100. For example, a material of the third pixel defining structure 330 may be an inorganic material.

In S6100, a second groove is prepared in a second defining sidewall.

Specifically, referring to step k in FIG. 21, the third pixel defining structure 330 includes a second defining sidewall 331a facing one side of a pixel opening 311, and a second groove 331b is disposed in the second defining sidewall 331a. The second groove 331b is equivalent to a recessed region of the second defining sidewall 331a. At least one of the multiple light-emitting layers 220 prepared subsequently is disconnected at the second groove 331b, thereby avoiding leakage current transmission of holes or electrons between different light-emitting elements, avoiding crosstalk between the different light-emitting elements and ensuring the display effect of the display panel.

In S6110, multiple light-emitting layers are prepared on a side of the first electrode facing away from the driving substrate.

Specifically, referring to step 1 in FIG. 21, multiple light-emitting layers 220 are prepared on a side of the first electrode 210 facing away from the driving substrate 100. The light-emitting layer 220 is disconnected at the second groove 331b may be the case where at least some films in the light-emitting layer 220 are disconnected (for example, only a hole injection layer 221 and a hole transport layer 222 are disconnected) or may be the case where the second groove 331b is filled with at least some films in the light-emitting layer 220, which is equivalent to increasing a transmission path. For the specific case where a film in the light-emitting layer 220 is disconnected at the second groove 331b, a process can be adjusted according to different requirements, thereby implementing different disconnections of films. Reference may also be made to the display panel 10 shown in FIG. 5. It is to be noted that FIG. 5 may be understood as a display panel prepared after step k.

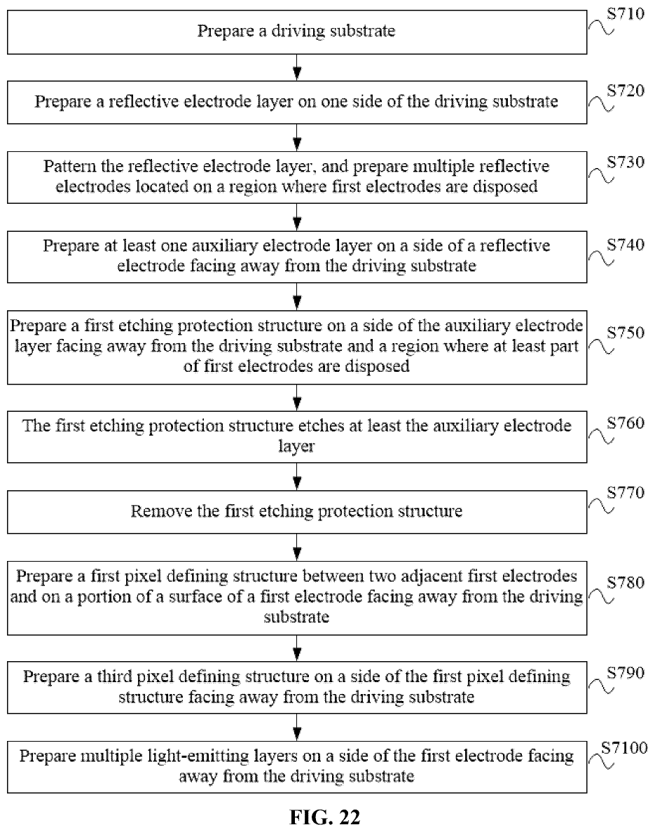

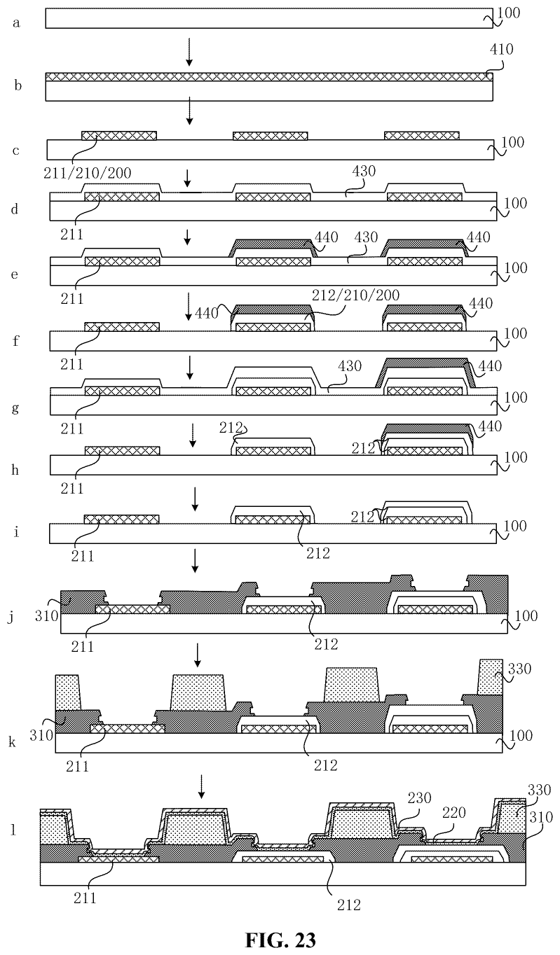

Optionally, FIG. 22 is a flowchart of a seventh preparation method of a display panel according to an embodiment of the present disclosure. FIG. 23 is a schematic diagram of an eighth preparation process of a display panel according to an embodiment of the present disclosure. Referring to FIGS. 22 and 23, the preparation method of a display panel further includes the steps described below.

In S710, a driving substrate is prepared.

Specifically, referring to step a in FIG. 23, a driving substrate 100 is prepared.

In S720, a reflective electrode layer is prepared on one side of the driving substrate.

Specifically, referring to step b in FIG. 23, a reflective electrode layer 410 is prepared on one side of the driving substrate 100.

In S730, the reflective electrode layer is patterned, and multiple reflective electrodes located on a region where first electrodes are disposed are prepared.

Specifically, referring to step c in FIG. 23, the reflective electrode layer 410 is subjected to patterned etching, thereby preparing multiple reflective electrodes 211. A region where the reflective electrodes 211 are disposed may be understood as a region where first electrodes 210 are disposed.

In S740, at least one auxiliary electrode layer is prepared on a side of a reflective electrode facing away from the driving substrate.

Specifically, referring to step d in FIG. 23, at least one auxiliary electrode layer 430 is prepared on a side of a reflective electrode 211 facing away from the driving substrate 100. One auxiliary electrode layer 430 being prepared on the side of the reflective electrode 211 facing away from the driving substrate 100 is illustrated in step d in FIG. 23. The specific number of disposed auxiliary electrode layers 430 may be adaptively adjusted according to a requirement and is not specifically limited in the embodiment of the present disclosure.

In S750, a first etching protection structure is prepared on a side of the auxiliary electrode layer facing away from the driving substrate and a region where at least part of first electrodes are disposed.

Specifically, referring to step e in FIG. 23, a first etching protection structure 440 is disposed in a region where at least part of first electrodes are disposed and a side of the auxiliary electrode layer 430 facing away from the driving substrate 100. Subsequently, the reflective electrode layer 430 can be subjected to patterned etching by the first etching protection structure 440. It may be understood that in the region where the first electrodes are disposed, the first etching protection structure 440 is disposed and an auxiliary electrode layer 430 between the first etching protection structure 440 and the driving substrate 100 can remain, and in the region where the first electrodes are disposed, no first etching protection structure 440 is disposed, a corresponding auxiliary electrode layer 430 is removed in a subsequent etching process.

In S760, at least the auxiliary electrode layer is etched by the first etching protection structure.

Specifically, referring to step fin FIG. 23, for the auxiliary electrode layer 430, a region not covered by the first etching protection structure 440 is removed, and a region covered by the first etching protection structure 440 remains. An auxiliary electrode layer 430 remaining through etching is an auxiliary electrode 212. Referring to step f to step h in FIG. 23, different numbers of auxiliary electrode layers 430 may be disposed in different regions where first electrodes are disposed, and the first etching protection structure 440 may be prepared for multiple times, thereby implementing different numbers of layers of auxiliary electrodes 212 in the regions where the first electrodes are disposed, as shown in step g in FIG. 23.

Further, the auxiliary electrode 212 is prepared step by step so that the auxiliary electrode 212 can cover the reflective electrode 211, and among adjacent auxiliary electrodes 212, an auxiliary electrode 212 facing away from a side of the driving substrate 100 can cover an auxiliary electrode 212 facing the side of the driving substrate 100. Contact areas between the auxiliary electrode 212 and other films can be ensured, and the auxiliary electrode 212 being stably disposed on the side of the reflective electrode 211 facing away from the driving substrate 100 is ensured. It may be understood that a size of the auxiliary electrode 212 is adjusted to ensure the result stability of the auxiliary electrode 212.

In S770, the first etching protection structure is removed.

Specifically, referring to step i in FIG. 23, the first etching protection structure 440 is removed, and the reflective electrode 211 and the auxiliary electrode 212 remain on one side of the driving substrate 100.

In S780, a first pixel defining structure is prepared between two adjacent first electrodes and on a portion of a surface of a first electrode facing away from the driving substrate.

Specifically, referring to step j in FIG. 23, a first pixel defining structure 310 is prepared between two adjacent first electrodes 210 and on a portion of a surface of a first electrode 210 facing away from the driving substrate 100, and a material of the first pixel defining structure 310 may be an inorganic material. Further, the first pixel defining structure 310 includes a first defining sidewall 312a facing one side of a pixel opening 311, and the first defining sidewall 312a includes a first groove 312b. The first groove 312b is equivalent to a recessed region of the first defining sidewall 312a. At least one of the multiple light-emitting layers 220 in a light-emitting element is disconnected at the first groove 312b, thereby avoiding leakage current transmission of holes or electrons between different light-emitting elements 200, further avoiding crosstalk between the different light-emitting elements 200 and ensuring a display effect of the display panel 10.

In S790, a third pixel defining structure is prepared on a side of the first pixel defining structure facing away from the driving substrate.

Referring to step k in FIG. 23, a third pixel defining structure 330 is prepared on a side of the first pixel defining structure 310 facing away from the driving substrate 100. The third pixel defining structure 330 is disposed so that a thickness of an entire film can also be increased, and an extended path of a light-emitting layer 220 in a light-emitting element can be increased after the thickness is increased. Further, a leakage current between two adjacent light-emitting elements can be reduced, and light emission effects of the light-emitting elements 200 can be ensured, thereby improving the display effect of the entire display panel 10. For example, a material of the third pixel defining structure 330 may be an organic material.

In S7100, multiple light-emitting layers are prepared on a side of the first electrode facing away from the driving substrate.

Specifically, referring to step i in FIG. 23, multiple light-emitting layers 220 are prepared on a side of the first electrode 210 facing away from the driving substrate 100. The light-emitting layer 220 is disconnected at a second groove 331b may be the case where at least some films in the light-emitting layer 220 are disconnected (for example, only a hole injection layer 221 and a hole transport layer 222 are disconnected) or may be the case where the second groove 331b is filled with at least some films in the light-emitting layer 220, which is equivalent to increasing a transmission path. For the specific case where a film in the light-emitting layer 220 is disconnected at the second groove 331b, a process can be adjusted according to different requirements, thereby implementing different disconnections of films. Reference may also be made to the display panel 10 shown in FIG. 4. It is to be noted that FIG. 4 may be understood as a display panel prepared after step k.

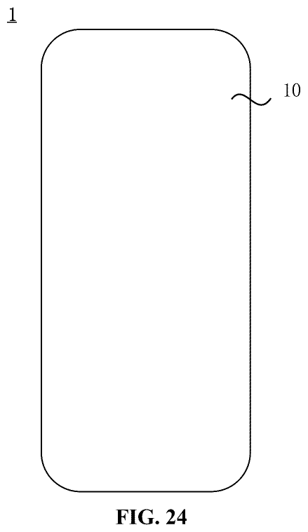

Based on the same inventive concept, an embodiment of the present disclosure further provides a display device. FIG. 24 is a structure diagram of a display device according to an embodiment of the present disclosure. As shown in FIG. 24, a display device 1 includes the display panel 10 according to any one of the preceding embodiments. Therefore, the display device 1 provided in the embodiment of the present disclosure has the corresponding beneficial effects in the preceding embodiments. The details are not repeated here. The display device 1 may be an electronic device such as a mobile phone, a computer, a smart wearable device (for example, a smartwatch) or an in-vehicle display device.

It is to be noted that the preceding are preferred embodiments of the present disclosure and technical principles used therein. It is to be understood by those skilled in the art that the present disclosure is not limited to the embodiments described herein. For those skilled in the art, various apparent modifications, adaptations, and substitutions can be made without departing from the scope of the present disclosure. Therefore, though the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising a driving substrate and a plurality of light-emitting elements located on one side of the driving substrate, wherein different light-emitting elements among the plurality of light-emitting elements have different light emission colors; and
the plurality of light-emitting elements comprise first electrodes, the first electrodes comprise reflective electrodes, and at least part of the first electrodes each further comprise at least one layer of auxiliary electrodes, wherein the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors have different thicknesses.

2. The display panel according to claim 1, wherein the light-emitting elements with the different light emission colors comprise a first light-emitting element and a second light-emitting element, wherein the first light-emitting element comprises a red light-emitting element or a green light-emitting element, and the second light-emitting element comprises a blue light-emitting element; or the first light-emitting element comprises a red light-emitting element, and the second light-emitting element comprises a green light-emitting element or a blue light-emitting element; and
a number of layers of auxiliary electrodes in the first light-emitting element is greater than a number of layers of auxiliary electrodes in the second light-emitting element.

3. The display panel according to claim 1, wherein the plurality of light-emitting elements comprise a third light-emitting element, and the third light-emitting element comprises at least one layer of auxiliary electrodes; and
an area of the at least one layer of auxiliary electrodes is S1, and an area of a reflective electrode is S2, wherein |S1−S2|/S1≤10%;
wherein the plurality of light-emitting elements comprise a fourth light-emitting element, the fourth light-emitting element comprises at least two layers of stacked auxiliary electrodes, and the at least two layers of auxiliary electrodes comprise a first auxiliary electrode and a second auxiliary electrode; and
an area of the first auxiliary electrode is S3, and an area of the second auxiliary electrode is S4, wherein |S3−S4|/S3≤10%.

4. The display panel according to claim 1, wherein the plurality of light-emitting elements comprise a fifth light-emitting element, and the fifth light-emitting element comprises at least one layer of auxiliary electrodes; and
the at least one layer of auxiliary electrodes covers an upper surface on a side of a reflective electrode facing away from the driving substrate and a side surface connected to the upper surface;
wherein the plurality of light-emitting elements comprise a sixth light-emitting element, the sixth light-emitting element comprises at least two layers of stacked auxiliary electrodes, and the at least two layers of auxiliary electrodes comprise a third auxiliary electrode and a fourth auxiliary electrode, wherein the fourth auxiliary electrode is located on a side of the third auxiliary electrode facing away from the driving substrate; and
the fourth auxiliary electrode covers an upper surface on the side of the third auxiliary electrode facing away from the driving substrate and a side surface connected to the upper surface.

5. The display panel according to claim 1, further comprising a first pixel defining structure at least partially located on a side of a first electrode facing away from the driving substrate, wherein a pixel opening is disposed in the first pixel defining structure, penetrates through the first pixel defining structure and exposes at least a portion of the first electrode; and
the first pixel defining structure covers a portion of an upper surface on the side of the first electrode facing away from the driving substrate.

6. The display panel according to claim 5, wherein the first pixel defining structure comprises a plurality of pixel defining sub-structures disposed independently and an inorganic pixel defining structure, wherein a pixel defining sub-structure of the plurality of pixel defining sub-structures corresponds to a respective one of the plurality of light-emitting elements; and
the pixel defining sub-structure covers a portion of an upper surface on a side of a first electrode facing away from the driving substrate in a light-emitting element corresponding to the pixel defining sub-structure, and an orthographic projection of the pixel defining sub-structure on a plane where the driving substrate is located is located within an orthographic projection of a first electrode in a light-emitting element corresponding to the pixel defining sub-structure on the plane where the driving substrate is located;
wherein the display panel further comprises a second pixel defining structure, and the second pixel defining structure comprises an organic pixel defining structure;
wherein the driving substrate comprises a planarization layer, and the first electrode is located on a side of the planarization layer facing away from the driver circuit; and
the second pixel defining structure covers at least a portion of a surface on a side of the first pixel defining structure facing away from the driving substrate and is in contact with and covers the planarization layer between two adjacent pixel defining sub-structures.

7. The display panel according to claim 5, wherein the driving substrate comprises a planarization layer, wherein the first electrode is located on a side of the planarization layer facing away from the driver circuit; and
the first pixel defining structure is further in contact with and covers the planarization layer between two adjacent first electrodes.

8. The display panel according to claim 7, further comprising a third pixel defining structure;
wherein the third pixel defining structure is located on a side of the first pixel defining structure facing away from the driving substrate and covers at least a portion of the first pixel defining structure;
wherein the first pixel defining structure comprises an organic pixel defining structure, and the third pixel defining structure comprises an inorganic pixel defining structure;
the third pixel defining structure covers a surface and a side surface on the side of the first pixel defining structure facing away from the driving substrate; and
the third pixel defining structure comprises a second defining sidewall facing one side of the pixel opening, wherein a second groove is disposed in the second defining sidewall and penetrates a portion of the second defining sidewall.

9. The display panel according to claim 5, wherein the first pixel defining structure comprises a first defining sidewall facing one side of the pixel opening, wherein a first groove is disposed in the first defining sidewall and penetrates through a portion of the first defining sidewall; and
a light-emitting element among the plurality of light-emitting elements further comprises a plurality of light-emitting layers located on the side of the first electrode facing away from the driving substrate, wherein at least one of the plurality of light-emitting layers is disconnected at a position of the first groove;
wherein the light-emitting elements with the different light emission colors comprise a first light-emitting element and a second light-emitting element; and
an organic pixel defining structure corresponding to the first light-emitting element and an organic pixel defining structure corresponding to the second light-emitting element have a same thickness.

10. The display panel according to claim 1, further comprising an organic pixel defining structure, wherein along a thickness direction of the display panel, the organic pixel defining structure overlaps a gap between at least two adjacent first electrodes; and
a thickness of the organic pixel defining structure is greater than or equal to a thickness of a first electrode among the first electrodes.

11. The display panel according to claim 1, wherein light-emitting elements with auxiliary electrodes comprise a seventh light-emitting element and an eighth light-emitting element;
a thickness of an auxiliary electrode in the seventh light-emitting element is D1, and a thickness of an auxiliary electrode in the eighth light-emitting element is D2;
wherein (n+1)/n≤D1/D2≤(n+1)/1, and n is a positive number.

12. A preparation method of a display panel, wherein the display panel comprises a plurality of light-emitting elements, wherein different light-emitting elements among the plurality of light-emitting elements have different light emission colors; and
the preparation method comprises:
preparing a driving substrate; and
preparing first electrodes on one side of the driving substrate, wherein the first electrodes comprise reflective electrodes, and at least part of the first electrodes each further comprise at least one layer of auxiliary electrodes, wherein the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors among the plurality of light-emitting elements have different thicknesses.

13. The preparation method according to claim 12, wherein preparing the first electrodes on the one side of the driving substrate comprises:
preparing a reflective electrode layer on one side of the driving substrate;
preparing at least one auxiliary electrode layer and a first etching protection structure on a side of the reflective electrode layer facing away from the driving substrate, wherein the etching protection structure is located on a region where at least part of the first electrodes are disposed; and
etching, by the first etching protection structure, the at least one auxiliary electrode layer.

14. The preparation method according to claim 13, wherein before preparing the at least one auxiliary electrode layer and the first etching protection structure on the side of the reflective electrode layer facing away from the driving substrate, the preparation method further comprises:
preparing a second etching protection structure on the side of the reflective electrode layer facing away from the driving substrate and a region where part of the first electrodes are disposed;
preparing the at least one auxiliary electrode layer and the first etching protection structure on the side of the reflective electrode layer facing away from the driving substrate comprises:
preparing the at least one auxiliary electrode layer on a side of the second etching protection structure facing away from the driving substrate; and
preparing the first etching protection structure on a side of the at least one auxiliary electrode layer facing away from the driving substrate and a region where remaining first electrodes among the first electrodes are disposed; and
etching, by the first etching protection structure, the at least one auxiliary electrode layer comprises:
etching, by the second etching protection structure, the reflective electrode layer, etching, by the first etching protection structure, the reflective electrode layer and the at least one auxiliary electrode layer, and obtaining reflective electrodes and auxiliary electrodes that are located in a region where the first electrodes are disposed.

15. The preparation method according to claim 14, wherein after etching, by the second etching protection structure, the reflective electrode layer, and etching, by the first etching protection structure, the reflective electrode layer and the at least one auxiliary electrode layer, the preparation method further comprises:
preparing a pixel opening in the etching protection structure, wherein the etching protection structure also serves as a first pixel defining structure for defining a light-emitting region of a light-emitting element among the plurality of light-emitting elements.

16. The preparation method according to claim 15, wherein the driving substrate comprises a planarization layer, wherein a first electrode among the first electrodes is located on a side of the planarization layer facing away from a driver circuit; and
preparing the pixel opening in the etching protection structure comprises:
preparing a second pixel defining layer, wherein the second pixel defining layer covers the etching protection structure and is in contact with and covers the planarization layer between two adjacent etching protection structures;
patterning the second pixel defining layer, and preparing a first pixel opening segment in the second pixel defining layer, wherein the first pixel opening segment penetrates through the second pixel defining layer located on a side of the etching protection structure facing away from the driving substrate to obtain a second pixel defining structure; and
etching, by using the first pixel opening segment, an etching protective layer, and preparing a second pixel opening segment in the etching protective layer, wherein the pixel opening comprises the first pixel opening segment and the second pixel opening segment.

17. The preparation method according to claim 15, wherein the driving substrate comprises a planarization layer, wherein a first electrode among the first electrodes is located on a side of the planarization layer facing away from a driver circuit; and
preparing the pixel opening in the etching protection structure comprises:
preparing a sacrificial pixel defining layer, wherein the sacrificial pixel defining layer covers the etching protection structure and is in contact with and covers the planarization layer between two adjacent etching protection structures;
patterning the sacrificial pixel defining layer, and preparing a third pixel opening segment in the sacrificial pixel defining layer, wherein the third pixel opening segment penetrates through the sacrificial pixel defining layer located on a side of the etching protection structure facing away from the driving substrate to obtain a sacrificial pixel defining structure;
etching, by using the third pixel opening segment, an etching protective layer, and preparing a fourth pixel opening segment in the etching protective layer;
removing the sacrificial pixel defining structure; and
preparing and patterning a second pixel defining layer, and preparing a fifth pixel opening segment in the second pixel defining layer, wherein the fifth pixel opening segment penetrates through the second pixel defining layer located on a side of the first electrode facing away from the driving substrate to obtain a second pixel defining structure, and the pixel opening comprises the fourth pixel opening segment and the fifth pixel opening segment.

18. The preparation method according to claim 15, wherein the first pixel defining structure comprises a first defining sidewall facing one side of the pixel opening; and
the preparation method further comprises:
preparing a first groove in the first defining sidewall, wherein the first groove penetrates through a portion of the first defining sidewall; and
preparing a plurality of light-emitting layers on a side of a first electrode among the first electrodes facing away from the driving substrate, wherein at least one of the plurality of light-emitting layers is disconnected at a position of the first groove;
wherein the first pixel defining structure comprises a plurality of stacked defining films; and
two adjacent defining films among the plurality of stacked defining films are made of different materials.

19. The preparation method according to claim 13, wherein before preparing the at least one auxiliary electrode layer and the first etching protection structure on the side of the reflective electrode layer facing away from the driving substrate, the preparation method further comprises:
patterning the reflective electrode layer, and preparing a plurality of reflective electrodes located on a region where the first electrodes are disposed; and
preparing the at least one auxiliary electrode layer and the first etching protection structure on the side of the reflective electrode layer facing away from the driving substrate comprises:
preparing the at least one auxiliary electrode layer on a side of a reflective electrode among the plurality of reflective electrodes facing away from the driving substrate; and
preparing the first etching protection structure on a side of the at least one auxiliary electrode layer facing away from the driving substrate and a region where at least part of the first electrodes are disposed;
wherein after etching, by the first etching protection structure, the at least one auxiliary electrode layer, the preparation method further comprises:
removing the first etching protection structure; and
preparing a first pixel defining structure between two adjacent first electrodes among the first electrodes and on a portion of a surface of a first electrode among the first electrodes facing away from the driving substrate;
wherein after preparing the first pixel defining structure between the two adjacent first electrodes among the first electrodes and on the portion of the surface of the first electrode among the first electrodes facing away from the driving substrate, the preparation method further comprises:
preparing a third pixel defining structure on a side of the first pixel defining structure facing away from the driving substrate, wherein the third pixel defining structure covers at least a portion of the first pixel defining structure;
wherein the first pixel defining structure comprises an organic pixel defining structure, and the third pixel defining structure comprises an inorganic pixel defining structure;
the third pixel defining structure covers a surface and a side surface on the side of the first pixel defining structure facing away from the driving substrate and comprises a second defining sidewall facing one side of a pixel opening; and
after preparing the third pixel defining structure on the side of the first pixel defining structure facing away from the driving substrate, the preparation method further comprises:
preparing a second groove in the second defining sidewall, wherein the second groove penetrates through a portion of the second defining sidewall; and
preparing a plurality of light-emitting layers on a side of the first electrode facing away from the driving substrate, wherein at least one of the plurality of light-emitting layers is disconnected at a position of the second groove.

20. A display device, comprising a display panel,
wherein the display panel comprises a driving substrate and a plurality of light-emitting elements located on one side of the driving substrate, wherein different light-emitting elements among the plurality of light-emitting elements have different light emission colors; and
the plurality of light-emitting elements comprise first electrodes, the first electrodes comprise reflective electrodes, and at least part of the first electrodes each further comprise at least one layer of auxiliary electrodes, wherein the reflective electrodes are electrically connected to a driver circuit in the driving substrate, the at least one layer of auxiliary electrodes is located on a side of a reflective electrode among the reflective electrodes facing away from the driving substrate, and auxiliary electrodes in the light-emitting elements with the different light emission colors have different thicknesses.
